(19) United States
(12) Patent Application Publication
(10) Pub. No.: US 2021/0202439 A1
(43) Pub. Date: Jul. 1, 2021

(54) HIGH POWER MODULE

(71) Applicant: Industrial Technology Research Institute, Hsin-chu (TW)

(72) Inventors: CHIH-CHIANG WU, Keelung City (TW); MING-TSAN PENG, Taoyuan County (TW); SHIH-KAI HSIEH, Taoyuan City (TW); LI-SONG LIN, Nantou County (TW); CHENG-HAN HO, Tainan City (TW); YEU-JOU LIN, Hsinchu County (TW)

(21) Appl. No.: 16/727,139

(22) Filed: Dec. 26, 2019

(51) Int. Cl. H01L 25/065; H01L 23/00; H01L 23/492; H01L 23/49

(52) U.S. Cl. CPC H01L 25/0655; H01L 24/48; H01L 24/49; H01L 2224/48247; H01L 23/49; H01L 2224/48095; H01L 2224/49176; H01L 23/492

(57) ABSTRACT

A high power module is provided, which includes a substrate, plural first power chips, plural second power chips, a positive electrode plate and a negative electrode plat. The substrate includes a first metal area, a second metal area, a third metal area disposed between the first metal area and the second metal area. The first power chips are disposed on the third metal area and connected to the first metal area via plural first connection elements. The second power chips are disposed on the second metal area and connected to the third metal area via plural second connection elements. The positive electrode plate is C-shaped and connected to the first metal area. The negative electrode plate is C-shaped and connected to the second metal area; the direction of the opening of the negative electrode plate is contrary to that of the opening of the positive electrode plate.

### TECHNICAL FIELD

The technical field relates to a high power module, in particular to a high power module capable of achieving low stray inductance and uniform current density.

### BACKGROUND

In general, a currently available high power module is integrated with multiple power chips so as to achieve high-current output, such that the high power module can satisfy the requirements of various vehicles and other relevant equipment, such as electric vehicles, motorcycles, buses, trucks, charging stations, etc. However, when the high power module is applied to a power inverter, the stray inductance of the switching circuits will result in overshoot during the switching period. Besides, the oscillation thereof will also incur electromagnetic interference (EMI) and serious switching loss.

Further, the stray inductance of currently available high power modules is very hard to be less than 10 nH (nano henry).

Moreover, currently available high power modules are likely to suffer the problem of non-uniform current density.

### SUMMARY

An embodiment of the disclosure relates to a high power module, which includes a substrate, a plurality of first power chips, a plurality of second power chips, a positive electrode plate, a negative electrode plate and an output electrode plate. The substrate includes a first metal area, a second metal area, and a third metal area disposed between the first metal area and the second metal area. The first power chips are disposed on the third metal area and the first power chips are connected to the first metal area via a plurality of first connection elements. The second power chips are disposed on the second metal area and the second power chips are connected to the third metal area via a plurality of second connection elements. The positive electrode plate is C-shaped and the positive electrode plate is connected to the first metal area. The negative electrode plate is C-shaped and the negative electrode is connected to the second metal area. The direction of the opening of the negative electrode plate is contrary to the direction of the opening of the positive electrode plate. The output electrode plate is connected to one end of the third metal area.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The disclosure will become more fully understood from the detailed description given herein below and the accompanying drawings which are given by way of illustration only, and thus are not limitative of the disclosure and wherein:

FIG. 1A˜FIG. 1D are structural diagrams of a high power module in accordance with a first embodiment of the disclosure.

FIG. 2A˜FIG. 2B are structural diagrams of the high power module integrated with a gate driving circuit in accordance with the first embodiment of the disclosure.

FIG. 3 is a structural diagram of a first power chip of the high power module in accordance with the first embodiment of the disclosure.

FIG. 4A is a stereogram view of a positive electrode plate/negative electrode plate of the high power module in accordance with the first embodiment of the disclosure.

FIG. 4B is a sectional view of the positive electrode plate/negative electrode plate of the high power module in accordance with the first embodiment of the disclosure.

FIG. 5A˜FIG. 5B are stereogram views of an output electrode plate of the high power module in accordance with the first embodiment of the disclosure.

FIG. 5C is a sectional view of the output electrode plate of the high power module in accordance with the first embodiment of the disclosure.

FIG. 6A is a side view of the high power module in accordance with the first embodiment of the disclosure.

FIG. 6B is a schematic view of an AC-phase current path of the high power module in accordance with the first embodiment of the disclosure.

FIG. 6C is a schematic view of a DC-phase current path of the high power module in accordance with the first embodiment of the disclosure.

FIG. 7A˜FIG. 7B are simulation results of the high power module in accordance with the first embodiment of the disclosure.

FIG. 8A˜FIG. 8C are structural diagrams of a high power module in accordance with a second embodiment of the disclosure.

FIG. 9 is a stereogram view of a positive electrode plate of the high power module in accordance with the second embodiment of the disclosure.

FIG. 10 is a stereogram view of a negative electrode plate of the high power module in accordance with the second embodiment of the disclosure.

FIG. 11A˜FIG. 11C are structural diagrams of a high power module in accordance with a third embodiment of the disclosure.

FIG. 12A˜FIG. 12B are local enlarged views of a positive electrode plate of the high power module in accordance with the third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

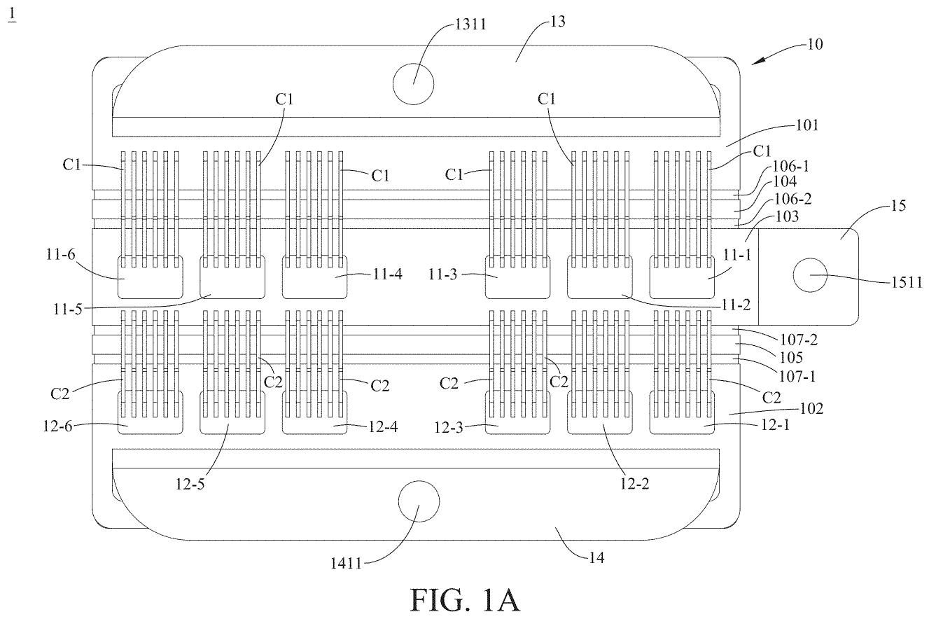

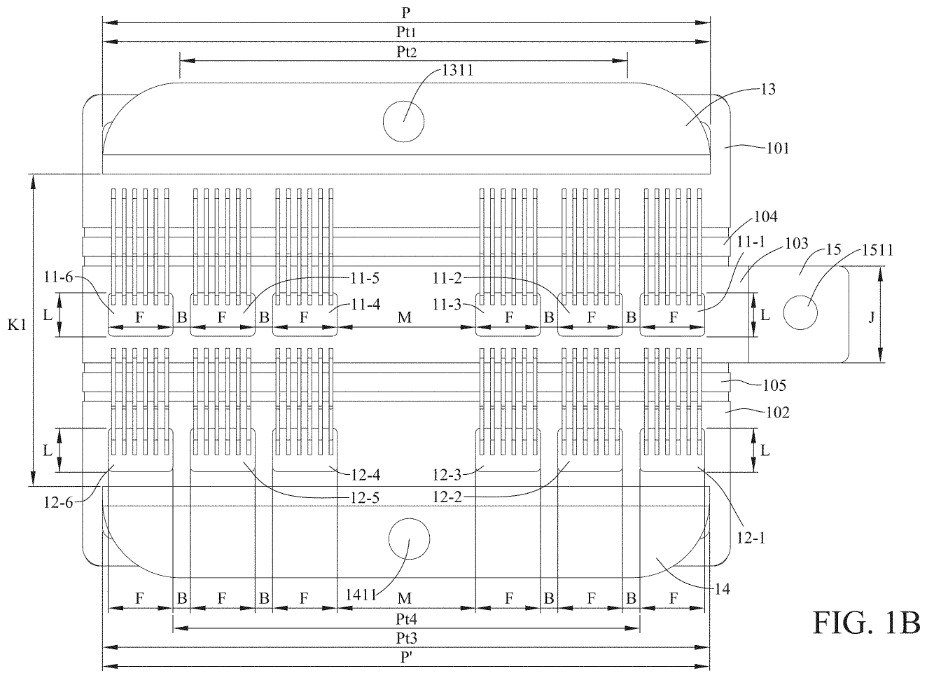

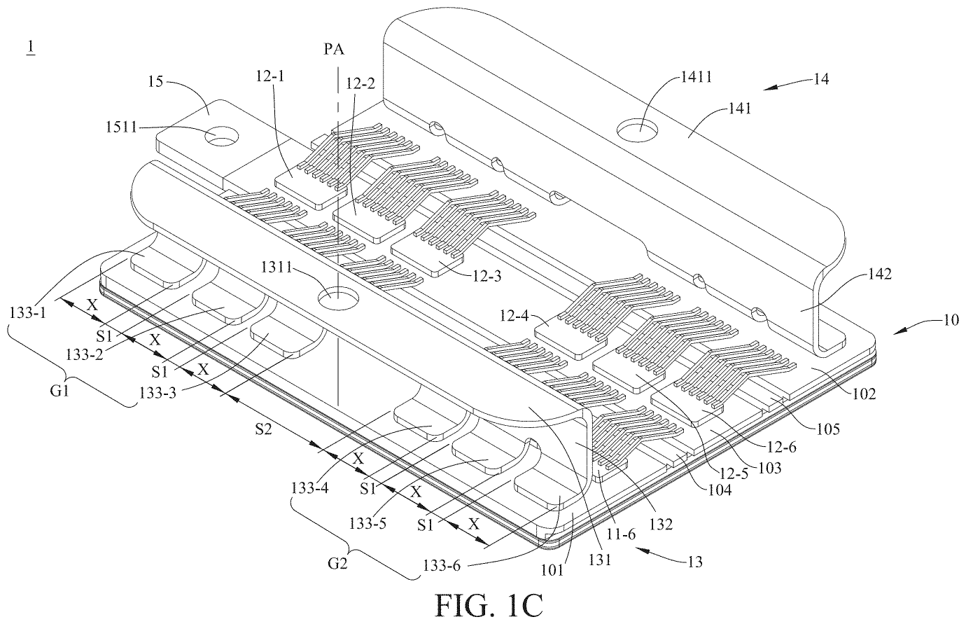

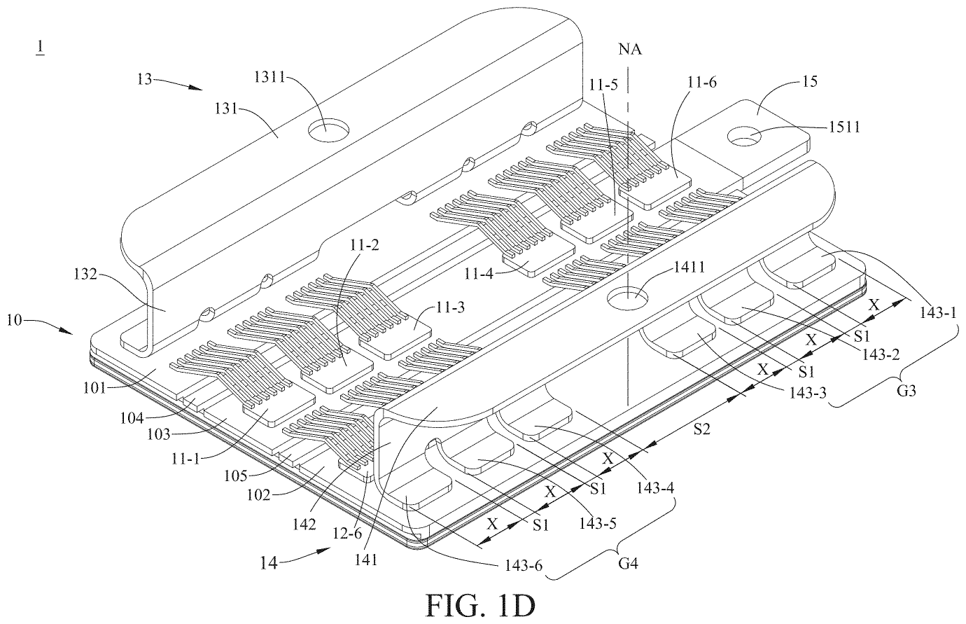

Please refer to FIG. 1A˜FIG. 1D, which are structural diagrams of a high power module 1 in accordance with a first embodiment of the disclosure. As shown in FIG. 1A, the high power module 1 includes a substrate 10, six first power chips 11-1, 11-2, 11-3, 11-4, 11-5, 11-6, six second power chips 12-1, 12-2, 12-3, 12-4, 12-5, 12-6, a positive electrode plate 13, a negative electrode plate 14 and an output electrode plate 15.

The substrate 10 includes a first metal area 101, a second metal area 102, a third metal area 103, a fourth metal area 104, a fifth metal area 105, a first upper isolation area 106-1, a first lower isolation area 106-2, a second upper isolation area 107-1 and a second lower isolation area 107-2. The first metal area 101, the second metal area 102 and the third metal area 103 are rectangular blocks. The third metal area 103 is disposed between the first metal area 101 and the second metal area 102. The fourth metal area 104 is disposed between the first metal area 101 and the third metal area 103, and the fourth metal area 104 is connected to the gates of the first power chips 11-1, 11-2, 11-3, 11-4, 11-5, 11-6. The first upper isolation area 106-1 and the first lower isolation area 106-2 are disposed at the two sides of the fourth metal area 104 respectively in order to isolate the fourth metal area 104 from the first metal area 101 and the third metal area 103. The fifth metal area 105 is disposed between the second metal area 102 and the third metal area 103, and the fifth metal area 105 is connected to the gates of the second power chips 12-1, 12-2, 12-3, 12-4, 12-5, 12-6. The second upper isolation area 107-1 and the second lower isolation area 107-2 are disposed at the two sides of the fifth metal area 105 respectively in order to isolate the fifth metal area 105 from the third metal area 103 and the second metal area 102.

The fourth metal area 104 and the fifth metal area 105 are connected to an external gate driving circuit (not shown in the drawings). Thus, the gates of the first power chips 11-1, 11-2, 11-3, 11-4, 11-5, 11-6 can connect to the external gate driving circuit via the fourth metal area 104. Likewise, the gates of the second power chips 12-1, 12-2, 12-3, 12-4, 12-5, 12-6 can also connect to the external gate driving circuit via the fifth metal area 105.

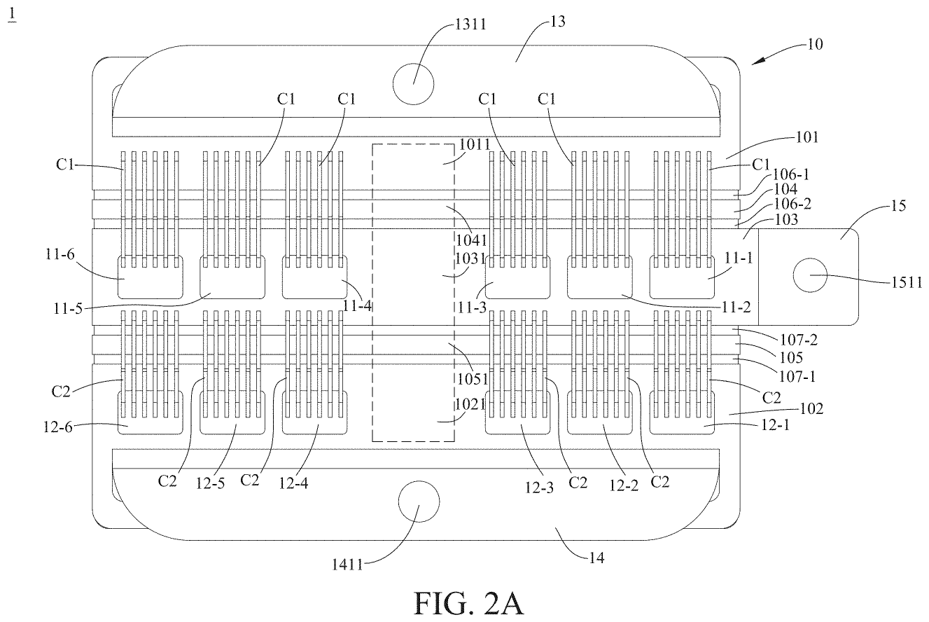

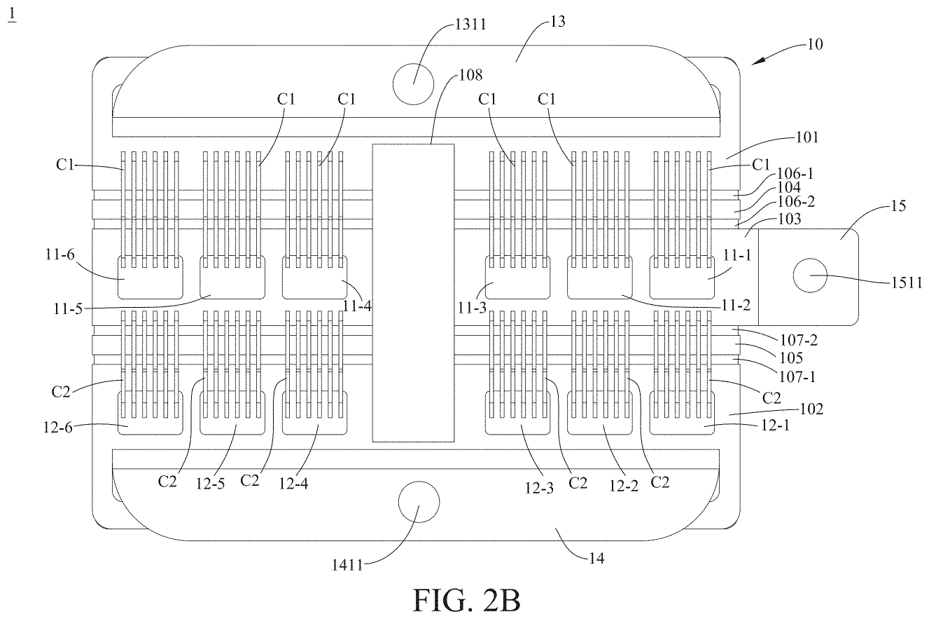

Please refer to FIG. 2A and FIG. 2B, which are structural diagrams of the high power module 1 integrated with a gate driving circuit 108 in accordance with the first embodiment of the disclosure. As shown in FIG. 2A, the first metal area 101 includes a first slot 1011. The second metal area 102 includes a second slot 1021. The third metal area 103 includes a third slot 1031. The fourth metal area 104 includes a fourth slot 1041. The fifth metal area 105 includes a fifth slot 1051. Therefore, as shown in FIG. 2B, the gate driving circuit 108 can be disposed in the space formed by the first slot 1011, the second slot 1021, the third slot 1031, the fourth slot 1041 and the fifth slot 1051. The gate driving circuit 108 and the traces thereof can be fixed by packaging technique, such that the gate driving circuit 108 can be stably installed on the substrate 10. Via the above structure, the high power module 1 does not need to connect to an external gate driving circuit, so the size of the high power module 1 can be significantly reduced and the high power module 1 can be more comprehensive in application. In another embodiment, the substrate 10 may include a slot and the gate driving circuit 108 may be disposed in the slot. In this way, the gate driving circuit 108 can be wrapped by the substrate 10 and the first-fifth metal areas 101-105.

As shown in FIG. 1A, the first power chips 11-1, 11-2, 11-3, 11-4, 11-5, 11-6 are disposed on the third metal area 103 and connected to the first metal area 101 via first connection elements C1. Therefore, the first connection elements C1 extend from the first metal area 101 to the third metal area 103, span the fourth metal area 104, and the first connection elements C1 connect/bridges the first power chips 11-1, 11-2, 11-3, 11-4, 11-5, 11-6 to the first metal area 101. In this way, the first power chips 11-1, 11-2, 11-3, 11-4, 11-5, 11-6 can be arranged in a straight line to form an array. In the embodiment, the gate g of the first power chip 11-1 is connected to the fourth metal area 104 via the traces, and the gate g is further connected to an external gate driving circuit. Similarly, the first power chips 11-2, 11-3, 11-4, 11-5, 11-6 also have the above structure.

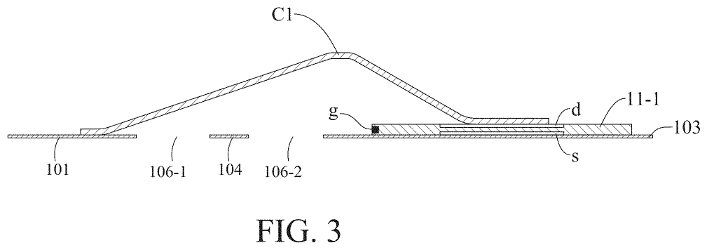

Please refer to FIG. 3, which is the structural diagram of the first power chip 11-1; please also refer to FIG. 1A. As shown in FIG. 3 and FIG. 1A, the sources of the first power chip 11-1 is disposed on the lower surface thereof, and the source s is connected to the third metal area 103. The drain d of the first power chip 11-1 is disposed on the upper surface thereof, and the drain d is connected to the first connection element C1. Likewise, the first power chips 11-2, 11-3, 11-4, 11-5, 11-6 also have the above structure. As described above, the sources s of the first power chips 11-1, 11-2, 11-3, 11-4, 11-5, 11-6 are connected to the third metal area 103, and the drains d of the first power chips 11-1, 11-2, 11-3, 11-4, 11-5, 11-6 are disposed on the upper surfaces thereof. Besides, one end of each of the first connection elements C1 is connected to the drain d of one of the first power chips 11-1, 11-2, 11-3, 11-4, 11-5, 11-6, so the drain d is connected to the first metal area 101 via the first connection element C1. The other end of each of the first connection elements C1 is connected to the first metal area 101. Accordingly, the first power chips 11-1, 11-2, 11-3, 11-4, 11-5, 11-6 are connected to each other in parallel. In one embodiment, the first power chips 11-1, 11-2, 11-3, 11-4, 11-5, 11-6 may be connected to the third metal area 103 by ribbon bonding, clip bonding, wire bonding, beam lead, surface mount technique (SMT), flip-chip, lead frame, ball grid array (BGA), etc. Besides, the first connection elements C1 may be bonding wires, copper sheets or other metal sheets. In the embodiment, the first power chips 11-1, 11-2, 11-3, 11-4, 11-5, 11-6 are connected to the third metal area 103 by wire bonding or clip bonding.

As shown in FIG. 1A, the second power chips 12-1, 12-2, 12-3, 12-4, 12-5, 12-6 are disposed on the second metal area 102 and connected to the third metal area 103 via second connection elements C2. Therefore, the second connection elements C2 extend from the second metal area 102 to the third metal area 103, span the fifth metal area 105, and the second connection elements C2 connect/bridge the second power chips 12-1, 12-2, 12-3, 12-4, 12-5, 12-6 to the third metal area 103. In this way, the second power chips 12-1, 12-2, 12-3, 12-4, 12-5, 12-6 can be arranged in a straight line to form another array. Accordingly, the second power chips 12-1, 12-2, 12-3, 12-4, 12-5, 12-6 can be symmetric to the first power chips 11-1, 11-2, 11-3, 11-4, 11-5, 11-6. In the embodiment, the gate g of the second power chip 12-1 is connected to the fifth metal area 105 via the traces and the gate g is further connected to the external gate driving circuit. Similarly, the second power chips 12-2, 12-3, 12-4, 12-5, 12-6 also have the above structure. As described above, the sources s of the second power chips 12-1, 12-2, 12-3, 12-4, 12-5, 12-6 are connected to the third metal area 103 (the side views of the second power chips 12-2, 12-3, 12-4, 12-5, 12-6 are identical to FIG. 3) and the drains d of the second power chips 12-1, 12-2, 12-3, 12-4, 12-5, 12-6 are disposed on the upper surfaces thereof. Besides, one end of each of the second connection elements C2 is connected to the drain d of one of the second power chips 12-1, 12-2, 12-3, 12-4, 12-5, 12-6, so the drain d is connected to the third metal area 103 via the second connection element C2. The other end of each of the second connection elements C2 is connected to the third metal area 103. Accordingly, the second power chips 12-1, 12-2, 12-3, 12-4, 12-5, 12-6 are connected to each other in parallel. According to FIG. 1, the first power chips 11-1, 11-2, 11-3, 11-4, 11-5, 11-6 are arranged in a straight line to form an array, and the second power chips 12-1, 12-2, 12-3, 12-4, 12-5, 12-6 are also arranged in a straight line to form another array. Thus, the array formed by the first power chips 11-1, 11-2, 11-3, 11-4, 11-5, 11-6 can be parallel to the array of the second power chips 12-1, 12-2, 12-3, 12-4, 12-5, 12-6. In a similar way, the second power chips 12-1, 12-2, 12-3, 12-4, 12-5, 12-6 may be connected to the second metal area 102 by ribbon bonding, clip bonding, wire bonding, beam lead, surface mount technique, flip-chip, lead frame, ball grid array, etc. In the embodiment, the second power chips 12-1, 12-2, 12-3, 12-4, 12-5, 12-6 are connected to the second metal area 102 by wire bonding or clip bonding. In one embodiment, the first power chips 11-1, 11-2, 11-3, 11-4, 11-5, 11-6 and the second power chips 12-1, 12-2, 12-3, 12-4, 12-5, 12-6 may be a SiC power switch, such as Silicon Carbide Power MOSFET (CPM3-0900-0010A; 900V/196A/10 mohm) provided by Wolfspeed Inc., other similar or advanced electronic components.

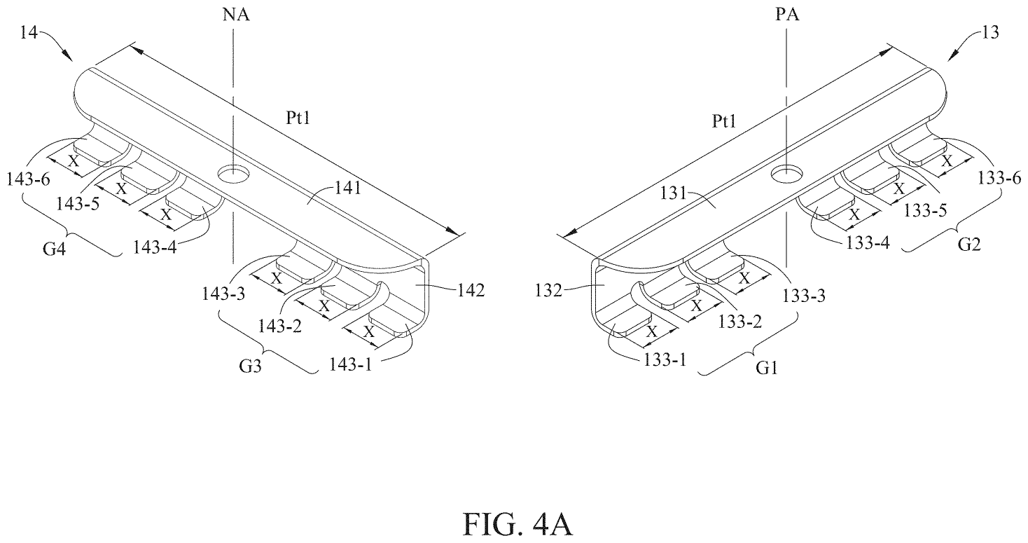

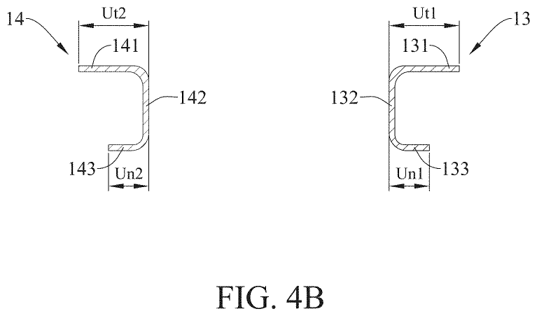

Please refer to FIG. 4A and FIG. 4B, which is a stereogram view and a sectional view of the positive electrode plate 13/negative electrode plate 14 of the high power module 1 in accordance with the first embodiment of the disclosure respectively. Please also refer to FIG. 1C-FIG. 1D. The positive electrode plate 13 is connected to the first metal area 101 and the positive electrode plate 13 is disposed at one side of the first power chips 11-1, 11-2, 11-3, 11-4, 11-5, 11-6. As shown in FIG. 4A and FIG. 4B, the positive electrode plate 13 includes a positive terminal 131, a connection portion 132 and six positive pins 133-1, 133-2, 133-3, 133-4, 133-5, 133-6. The positive terminal 131 is connected to the positive pins 133-1, 133-2, 133-3, 133-4, 133-5, 133-6 via the connection portion 132, such that the positive electrode plate 13 can be C-shaped. More specifically, the connection portion 132 can be considered a side wall. The positive pins 133-1, 133-2, 133-3, 133-4, 133-5, 133-6 and the positive terminal 131 are disposed on two planes respectively and the two planes are parallel to each other. The positive pins 133-1, 133-2, 133-3, 133-4, 133-5, 133-6 are corresponding to one positive electrode terminal 131. As shown in FIG. 4B (the sectional view), the width Ut1 of the positive terminal 131 is greater than the width Un1 of the positive pin 133-1. The positive pins 133-1, 133-2, 133-3, 133-4, 133-5, 133-6 can be divided into two groups, the first group G1 and the second group G2. The first group G1 and the second group G2 are disposed at the two sides of the central axis PA of the positive electrode plate 13 respectively. The first group G1 includes the positive pins 133-1, 133-2, 133-3 and the positive pins 133-1, 133-2, 133-3 are evenly spaced, where the interval between any two adjacent pins is S1. Similarly, the second group G2 includes the positive pins 133-4, 133-5, 133-6 and the positive pins 133-4, 133-5, 133-6 are evenly spaced, where the interval between any two adjacent pins is also S1. Further, the interval between the first group G1 and the second group G2 is S2 (i.e. the interval between the positive pin 133-3 and the positive pin 133-4), and S2 is greater than S1. The positive terminal 131 has a screw hole 1311 disposed at the central axis PA, so the positive terminal 131 can be electrically connected to external circuits. Therefore, after entering the positive terminal 131, the current passes through the connection portion 132 and the current is distributed over the six positive pins 133-1, 133-2, 133-3, 133-4, 133-5, 133-6. The width Pt1 of a connection end, the positive terminal 131 connecting to the connection portion 132, is equal to the width of the connection portion 132. Besides, the width Pt1 of the connection end, the positive terminal 131 connecting to the connection portion 132, is also equal to the width P of the positive electrode plate 13, as shown in FIG. 1B. The width Pt2 of the other end of the positive terminal 131 is less than the width Pt1 and the two sides of the positive terminal 131 are circular-arc-shaped. The positive pins 133-1, 133-2, 133-3, 133-4, 133-5, 133-6 directly contact the first metal area 101, and the positive pins 133-1, 133-2, 133-3, 133-4, 133-5, 133-6 are corresponding to the first power chips 11-1, 11-2, 11-3, 11-4, 11-5, 11-6 in position. According to FIG. 1A and FIG. 4B, the positive electrode plate 13 is C-shaped and the opening of the positive electrode plate 13 faces the direction away from the first power chips 11-1, 11-2, 11-3, 11-4, 11-5, 11-6. In the embodiment, the positive pins 133-1, 133-2, 133-3, 133-4, 133-5, 133-6 are rectangle-shaped. In another embodiment, the positive pins 133-1, 133-2, 133-3, 133-4, 133-5, 133-6 are square-shaped, trapezoid-shaped or in other different shapes.

Please refer to FIG. 4A, FIG. 4B and FIG. 1D. The negative electrode plate 14 is connected to the second metal area 102 and the negative electrode plate 14 is disposed at one side of the second power chips 12-1, 12-2, 12-3, 12-4, 12-5, 12-6. The structure of the negative electrode plate 14 is the same as that of the positive electrode 13. The negative electrode plate 14 includes a negative terminal 141, a connection portion 142 and six negative pins 143-1, 143-2, 143-3, 143-4, 143-5, 143-6. The negative terminal 141 is connected to the negative pins 143-1, 143-2, 143-3, 143-4, 143-5, 143-6 via the connection portion 142, such that the negative electrode plate 14 can be C-shaped. Likewise, the connection portion 142 can be considered a side wall. The negative pins 143-1, 143-2, 143-3, 143-4, 143-5, 143-6 and the negative terminal 141 are disposed on two planes respectively and the two planes are parallel to each other. The negative pins 143-1, 143-2, 143-3, 143-4, 143-5, 143-6 are corresponding to one negative electrode terminal 141. As shown in FIG. 4B (the sectional view), the width Ut2 of the negative terminal 141 is greater than the width Un2 of the negative pin 143-1. The negative pins 143-1, 143-2, 143-3, 143-4, 143-5, 143-6 can be divided into two groups, the third group G3 and the fourth group G4. The third group G3 and the fourth group G4 are disposed at the two sides of the central axis NA of the negative electrode plate 14 respectively. The third group G3 includes the negative pins 143-1, 143-2, 143-3 and the negative pins 143-1, 143-2, 143-3 are evenly spaced, where the interval between any two adjacent pins is S1. Similarly, the fourth group G4 includes the negative pins 143-4, 143-5, 143-6 and the negative pins 143-4, 143-5, 143-6 are evenly spaced, where the interval between any two adjacent pins is also S1. Further, the interval between the third group G3 and the fourth group G4 is S2 (i.e. the interval between the negative pin 143-3 and the negative pin 143-4), and S2 is greater than S1. The negative terminal 141 has a screw hole 1411 disposed at the central axis NA, so the negative terminal 141 can be electrically connected to external circuits. Therefore, after entering the negative terminal 141, the current passes through the connection portion 142 and the current is distributed over the six negative pins 143-1, 143-2, 143-3, 143-4, 143-5, 143-6. Similarly, the width Pt3 of a connection end, the negative terminal 141 connecting to the connection portion 142, is equal to the width of the connection portion 142. Besides, the width Pt3 of the connection end, the negative terminal 141 connecting to the connection portion 142, is equal to the width P′ of the negative electrode plate 14, as shown in FIG. 1B. The width Pt4 of the other end of the negative terminal 141 is less than the width Pt3 and the two sides of the negative terminal 141 are circular-arc-shaped. The negative pins 143-1, 143-2, 143-3, 143-4, 143-5, 143-6 directly contact the second metal area 102, and the negative pins 143-1, 143-2, 143-3, 143-4, 143-5, 143-6 are corresponding to the second power chips 12-1, 12-2, 12-3, 12-4, 12-5, 12-6 in position. Likewise, the opening of the negative electrode plate 14 faces the direction away from the second power chips 12-1, 12-2, 12-3, 12-4, 12-5, 12-6, such that the negative electrode plate 14 is corresponding and symmetric to the positive electrode plate 13. In the embodiment, the negative pins 143-1, 143-2, 143-3, 143-4, 143-5, 143-6 are rectangle-shaped. In another embodiment, the negative pins 143-1, 143-2, 143-3, 143-4, 143-5, 143-6 are square-shaped, trapezoid-shaped or in other different shapes.

As described above, the positive electrode plate 13 and the negative electrode plate 14 of the high power module 1 do not directly in a flat manner contact the first metal area 101 and the second metal area 102. That is to say, the positive electrode plate 13 and the negative electrode plate 14 contact the first metal area 101 and the second metal area 102 via the fingerlike positive pins 133-1, 133-2, 133-3, 133-4, 133-5, 133-6 and fingerlike negative pins 143-1, 143-2, 143-3, 143-4, 143-5, 143-6 respectively. Moreover, the quantities of the fingerlike positive pins 133-1, 133-2, 133-3, 133-4, 133-5, 133-6 and negative pins 143-1, 143-2, 143-3, 143-4, 143-5, 143-6 are also corresponding to the quantities of the first power chips 11-1, 11-2, 11-3, 11-4, 11-5, 11-6 and the second power chips 12-1, 12-2, 12-3, 12-4, 12-5, 12-6 respectively. The above design can effectively reduce the stray inductance of the high power module 1. In one embodiment, all pins are aligned with all power chips respectively.

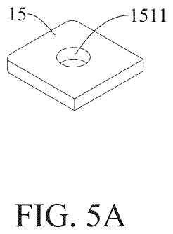

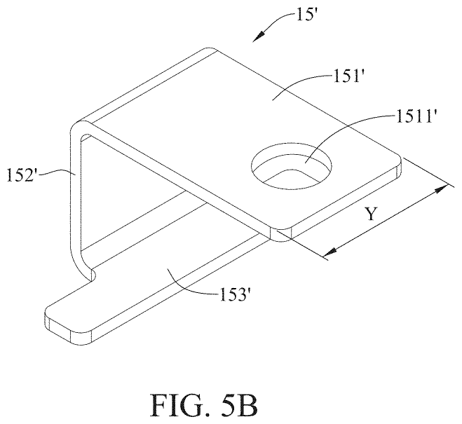

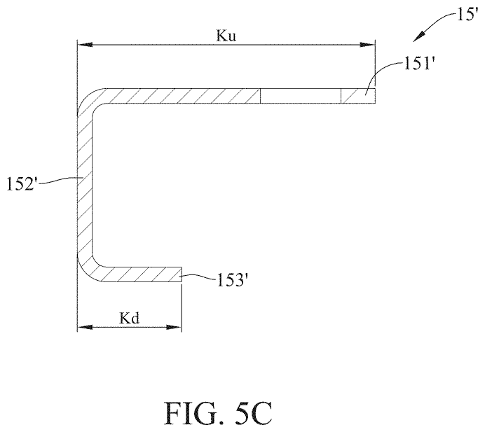

Please refer to FIG. 5A, which is a stereogram view of an output electrode plate 15 of the high power module 1 in accordance with the first embodiment of the disclosure; please also refer to FIG. 1A. As shown in FIG. 1A, the output electrode plate 15 is connected to one end of the third metal area 103. As shown in FIG. 5, the output electrode plate 15 is a flat metal sheet. In addition, the output electrode plate 15 also has a screw hole 1511.

Please refer to FIG. 5B and FIG. 5C, which are a stereogram view and a sectional view of an output electrode plate 15′ of the high power module 1 in accordance with the first embodiment of the disclosure respectively. As shown in FIG. 5B, the output electrode plate 15 of FIG. 15A can be replaced by the output electrode plate 15′. The output electrode plate 15′ can also be C-shaped and the direction of the opening of the output electrode plate 15 is perpendicular to the direction of the opening of the positive electrode plate 13 and the direction of the opening of the negative electrode plate 14. The output electrode plate 15′ includes an output terminal 151′, a connection portion 152′ and an output pin 153′. The output terminal 151′ is connected to the output pin 153′ via the connection portion 152′. Besides, the output terminal 151′ has a screw hole 1511′ and a widened structure. In other words, the width Y of the output terminal 151′ is greater than the width F of one first power chip (or one second power chip) and less than the width 2F of two first power chips (or two second power chips) (the width F of the first power chip or the second power chip is as shown in FIG. 1B), as shown in Equation (1) given below:

F<Y<2F (1)

Further, as shown in FIG. 5C, the width Ku of the output terminal 151′ is greater than the width Kd of the output pin 153′. The output terminal 151′ is parallel to the output pin 153′.

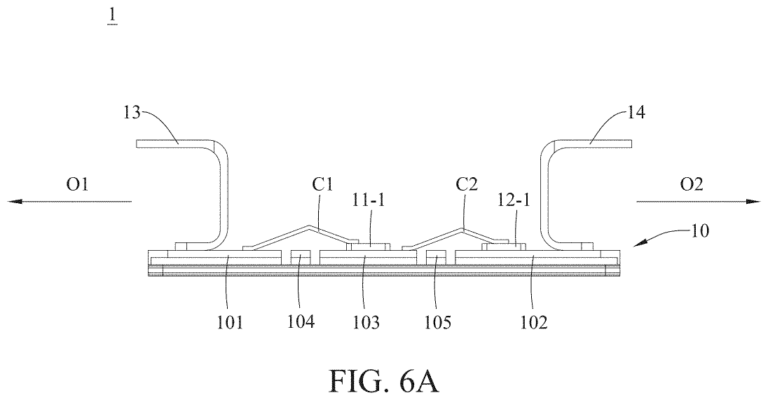

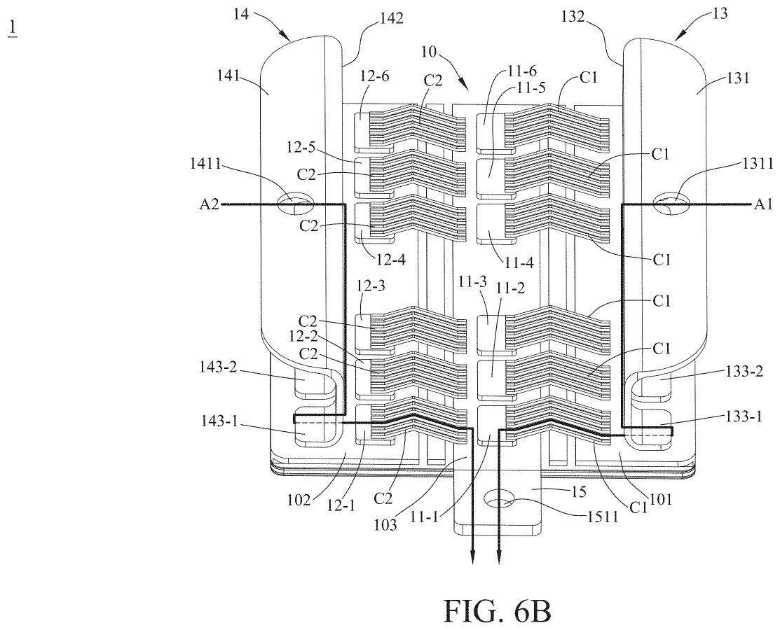

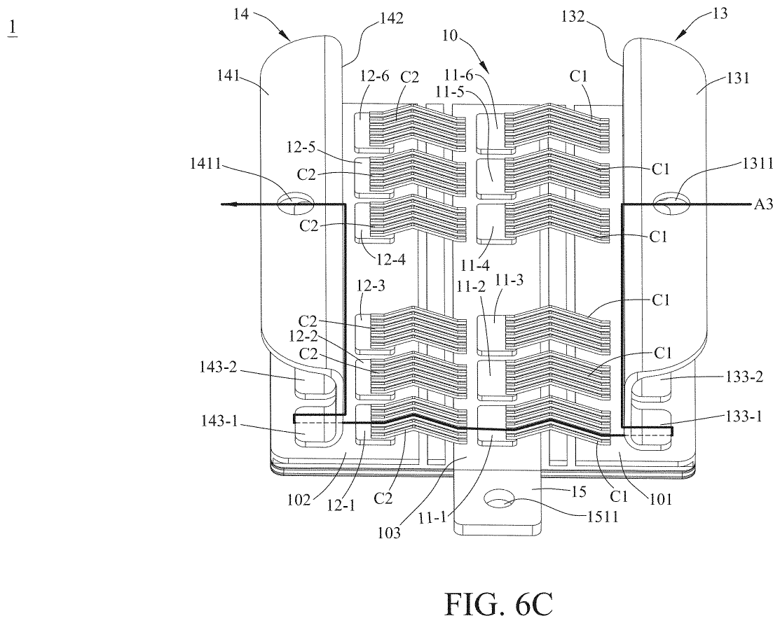

Please refer to FIG. 6A, FIG. 6B and FIG. 6C, which are a side view, a schematic view of an AC-phase current path and a schematic view of an DC-phase current path of the high power module 1 in accordance with the first embodiment of the disclosure respectively. As shown in FIG. 6A, the positive electrode plate 13 and the negative electrode plate 14 of the high power module 1 are C-shaped. Besides, the direction O1 of the opening of the positive electrode plate 13 is contrary to the direction O2 of the opening of the negative electrode plate 14 (i.e. the positive electrode plate 13 and the negative electrode plate 14 are disposed back to back).

As shown in FIG. 6B, the arrows A1 and A2 stand for the AC-phase current paths of the positive electrode plate 13 and the negative electrode plate 14 (FIG. 6B partially shows the current paths in order to more clearly illustrate the current paths). The AC current path A1 of the positive electrode plate 13 is: positive terminal 131->connection portion 132->positive pins 133-1, 133-2, 133-3, 133-4, 133-5, 133-6 (the current is distributed over the six pins)->first metal area 101->first connection elements C1->first power chips 11-1, 11-2, 11-3, 11-4, 11-5, 11-6->third metal area 103->output electrode plate 15. According to FIG. 6B, the current path (the current flows leftward in the figure) of the positive terminal 131 is contrary to the current path (the current flows rightward in the figure) of the positive pins 133-1, 133-2, 133-3, 133-4, 133-5, 133-6. Accordingly, the mutual inductance between the positive terminal 131 and the positive pins 133-1, 133-2, 133-3, 133-4, 133-5, 133-6 can be reduced, so the positive electrode plate 13 can achieve back coupling or antiphase coupling. The AC current path A2 of the negative electrode plate 14 is: negative terminal 141->connection portion 142->negative pins 143-1, 143-2, 143-3, 143-4, 143-5, 143-6->->second metal area 102->second power chips 12-1, 12-2, 12-3, 12-4, 12-5, 12-6->second connection elements C2->third metal area 103->output electrode plate 15. According to FIG. 6B, the current path (the current flows rightward in the figure) of the negative terminal 141 is contrary to the current path (the current flows leftward in the figure) of the negative pins 143-1, 143-2, 143-3, 143-4, 143-5, 143-6. Accordingly, the mutual inductance between the negative terminal 141 and the negative pins 143-1, 143-2, 143-3, 143-4, 143-5, 143-6 can be reduced, so the negative electrode plate 14 can also achieve back coupling or antiphase coupling.

As shown in FIG. 6C, the arrows A3 and A4 stand for the DC-phase current paths of the positive electrode plate 13 and the negative electrode plate 14 respectively. The DC current path A3 of the positive electrode plate 13 is: positive terminal 131->connection portion 132->positive pins 133-1, 133-2, 133-3, 133-4, 133-5, 133-6 (the current is distributed over the six pins)->first metal area 101->first connection elements C1->first power chips 11-1, 11-2, 11-3, 11-4, 11-5, 11-6->third metal area 103->second connection elements C2->second power chips 12-1, 12-2, 12-3, 12-4, 12-5, 12-6->second metal area 102->negative pins 143-1, 143-2, 143-3, 143-4, 143-5, 143-6 (the currents from the six pins converge into one terminal)->connection portion 142->negative terminal 141. According to FIG. 6C, the current path (the current flows leftward in the figure) of the positive terminal 131 is also contrary to the current path (the current flows rightward in the figure) of the positive pins 133-1, 133-2, 133-3, 133-4, 133-5, 133-6. Accordingly, the mutual inductance between the positive terminal 131 and the positive pins 133-1, 133-2, 133-3, 133-4, 133-5, 133-6 can be decreased, so the positive electrode plate 13 can achieve back coupling or antiphase coupling. Similarly, the negative electrode plate 14 can also achieve back coupling or antiphase coupling.

Accordingly, the positive electrode plate 13 and the negative electrode plate 14 can achieve back coupling or antiphase coupling in both AC phase and DC phase, such that the stray inductance of the high power module 1 can be effectively diminished.

As shown in FIG. 1B, in the embodiment, the first power chips 11-1, 11-2, 11-3, 11-4, 11-5, 11-6 are corresponding to the second power chips 12-1, 12-2, 12-3, 12-4, 12-5, 12-6. Besides, there is a distance K1 between the positive electrode plate 13 and the negative electrode plate 14, and the positive electrode plate 13 and the negative electrode plate 14 are corresponding to each other. Further, the positive terminal 131 does not overlap the negative terminal 141 in the vertical direction (the direction perpendicular to the substrate 10, which is equal the normal vector of the substrate 10). Moreover, the direction O1 of the opening of the positive electrode plate 13 is contrary to the direction O2 of the opening of the negative electrode plate 14 (as shown in FIG. 6A). Furthermore, both of the positive electrode plate 13 and the negative electrode plate 14 can achieve back coupling or antiphase coupling, as shown in FIG. 6B and FIG. 6C. Via the above design, the mutual inductance of the positive electrode plate 13 in itself and the mutual inductance of the negative electrode plate 14 in itself can be decreased, which can further reduce the stray inductance of the high power module 1.

The high power module 1 of the embodiment has special structure design and conforms to some size requirements. As shown in FIG. 1B˜FIG. 1D (please also refer to FIG. 1A), the width X of each of the positive pins 133-1, 133-2, 133-3, 133-4, 133-5, 133-6 and the negative pins 143-1, 143-2, 143-3, 143-4, 143-5, 143-6 is greater than or equal to the width F of one of first power chips 11-1, 11-2, 11-3, 11-4, 11-5, 11-6 and the second power chips 12-1, 12-2, 12-3, 12-4, 12-5, 12-6 corresponding thereto. And the width X is less than the sum of the width F and the interval B between two of the chips adjacent to each other, as shown in Equation (2) given below:

F≤X<F+B (2)

In Equation (2), X stands for the width of each of the positive pins 133-1, 133-2, 133-3, 133-4, 133-5, 133-6 and the negative pins 143-1, 143-2, 143-3, 143-4, 143-5, 143-6. F stands for the width of each of the first power chips 11-1, 11-2, 11-3, 11-4, 11-5, 11-6 and the second power chips 12-1, 12-2, 12-3, 12-4, 12-5, 12-6. B stands for the interval between any two adjacent ones of the first power chips 11-1, 11-2, 11-3, 11-4, 11-5, 11-6 or the second power chips 12-1, 12-2, 12-3, 12-4, 12-5, 12-6.

In addition, the width P of the positive electrode plate 13 is greater than the sum of the total of the widths F of the first power chips 11-1, 11-2, 11-3, 11-4, 11-5, 11-6, the width M of the central recess of the positive electrode plate 13 and the total of intervals B between the first power chips 11-1, 11-2, 11-3, 11-4, 11-5, 11-6. And the width P of the positive electrode plate 13 is less than the width W of the first metal area 101, as shown in Equation (3) given below:

W>P>(N*F+M+(N−2)*B) (3)

In Equation (3), P stands for the width of the positive electrode plate 13. W stands for the width of the first metal area 101. N stands for the quantity of the first power chips 11-1, 11-2, 11-3, 11-4, 11-5, 11-6. F stands for the width of each of the first power chips 11-1, 11-2, 11-3, 11-4, 11-5, 11-6. M stands for the width of the central recess of the positive electrode plate 13. B stands for the interval between any two adjacent ones of the first power chips 11-1, 11-2, 11-3, 11-4, 11-5, 11-6.

The structures of the negative electrode plate 14 and the second power chips 12-1, 12-2, 12-3, 12-4, 12-5, 12-6 is identical the structures of the positive electrode plate 13 and the first power chips 11-1, 11-2, 11-3, 11-4, 11-5, 11-6, so will not be further described herein.

Besides, the stray inductance of the high power module 1 of the embodiment can also be further reduced via the widened positive terminal 131, negative terminal 141 and output electrode plate 15. The structure of the negative terminal 141 is similar to that of the positive terminal 131, so will not be further described herein.

Further, the width Pt1 of the connection end, the positive terminal 131 connected to the connection portion 132, is equal to the width P of the positive electrode plate 14. The width Pt2 of the other end of the positive terminal 131 is less than the width Pt1. And the width Pt2 is greater than or equal to a value of the width Pt1 subtracted by two of the widths F, as shown in Equation (4) given below:

Pt1(=W)>Pt2≥(Pt1−2F) (4)

In Equation (4), Pt2 stands for the width of the other end of the positive terminal 131. Pt1 stands for the width of the connection end, the positive terminal 131 connecting to the connection portion 132. F stands for the width of the first power chips 11-1, 11-2, 11-3, 11-4, 11-5, 11-6. The structure of the negative terminal 141 is similar to that of the positive terminal 131, so will not be further described herein.

The width J of the output electrode plate 15 is greater than the width F of one first power chip (or one second power chip), but less than the width 2F of two first power chips (or two second power chips), as shown in Equation (5) given below:

F<J<2F (5)

Via the above circuit design and structure design, the high power module 1 can effectively reduce the stray inductance thereof to be less than 10 nH (nano henry) when the switching frequency is at about 10 MHz. Thus, the high power module 1 can effectively prevent from overshoot and EMI, and the high power module 1 can effectively decrease the switching loss. Therefore, the service life of the high power module 1 can be extended and the performance thereof can be enhanced.

Accordingly, the high power module 1 can be effectively applied to various vehicle and other relevant equipment. A simulation experiment is performed for the embodiment by Q3D software (stray inductance extractor software) and the experimental data of the simulation experiment are as shown in Table 1 given below:

TABLE 1

| | | | | Width F | Interval B(mm) | |
|---|---|---|---|---|---|---|
| | Width | Width | Quantity N | and length | between any | |
| Width | P(mm) of | X(mm) of | of first | L(mm) of | two adjacent | |
| W(mm) of | positive | positive | power | first power | ones of first | Stray |
| first metal | electrode | pins | chips | chips | power chips | inductance |
| area 101 | plate | 133-1~133-6 | 11-1~11-6 | 11-1~11-6 | 11-1~11-6 | (nH) |
| 67 | 62.5 | 5.95 | 6 | 3.75/5.95 | 1.8 | 6.6 |

According to the above experimental data, the structure and the circuit design of the high power module 1 of the embodiment can actually reduce the stray inductance. The stray inductance of the high power module 1 can be lower than 10 nH (nano henry).

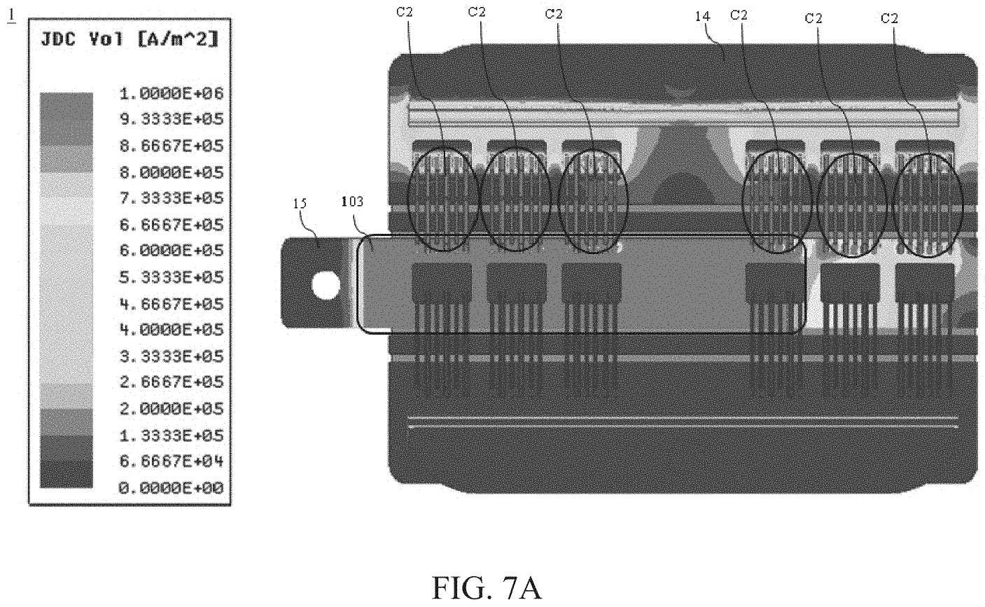

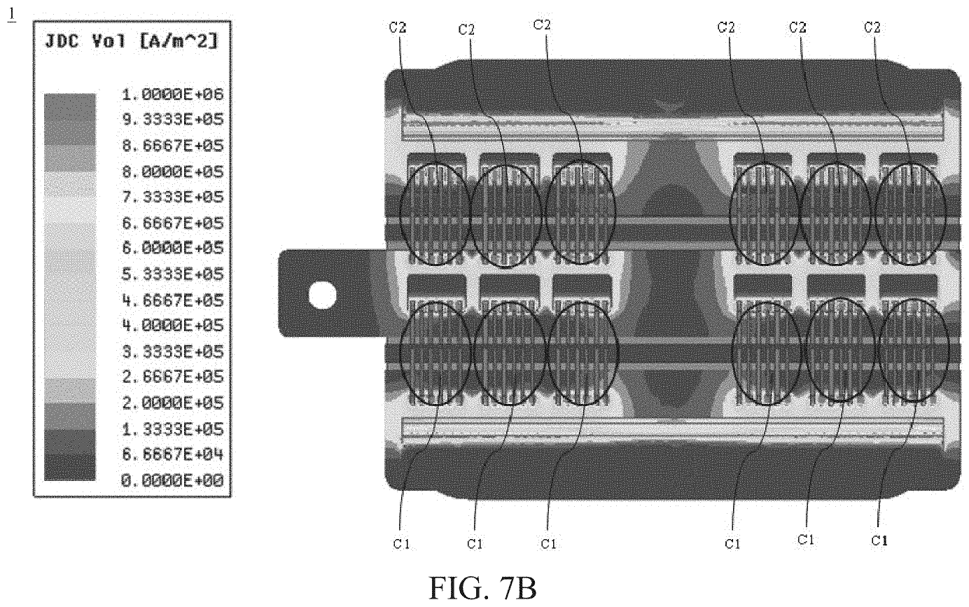

Please refer to FIG. 7A and FIG. 7B, which are simulation results of the high power module 1 in accordance with the first embodiment of the disclosure; please also refer to FIG. 1A.

FIG. 7A shows the current density simulation result obtained by simulating the AC-phase current path of the high power module 1 of the first embodiment. The simulation result is the current path shown by the arrow A2 of FIG. 6B (i.e. negative electrode plate 14->output electrode plate 15). As shown in FIG. 7A, the red zones mean the zones have higher current density (marked by the black circles). FIG. 7A clearly shows that the red zones are uniformly distributed over the second connection elements C2 and the third metal area 103, so the second connection elements C2 and the third metal area 103 have higher current density. When the high power module 1 operates at the power below 10 kw, the current density of the second connection elements C2 and the third metal area 103 can still remain below 20A/mm².

FIG. 7B shows the current density simulation result obtained by simulating the DC-phase current path of the high power module 1 of the first embodiment. The red zones mean the zones have higher current density (marked by the black circles). FIG. 7B clearly shows that the first connection elements C1 and the second connection elements C2 have higher current density. When the high power module 1 operates at the power below 10 kw, the first connection elements C1 and the second connection elements C2 can still remain below 20A/mm².

As set forth above, the current density, from the positive terminal 13 to the negative terminal 141, of the high power module 1 can be surely less than 20A/mm² (when the high power module 1 operates at the power below 10 kw). Thus, the temperature of the third metal area 103 can be kept within an acceptable range (100° C.). Accordingly, the high power module 1 will not malfunction as a result of excessively high temperature. In general, when the high power module 1 operates at the power below 10 kw, the current densities of the positive terminal 131, the negative terminal 141 and the output electrode plate 15 of the high power module 1 can be less than 20A/mm².

The embodiment just exemplifies the disclosure and is not intended to limit the scope of the disclosure. Any equivalent modification and variation according to the spirit of the disclosure is to be also included within the scope of the following claims and their equivalents.

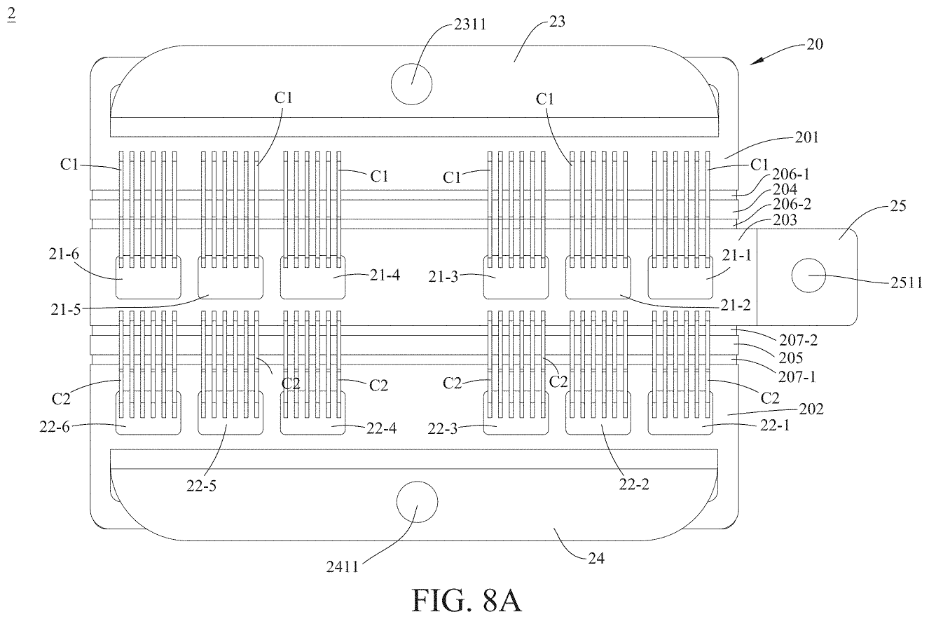

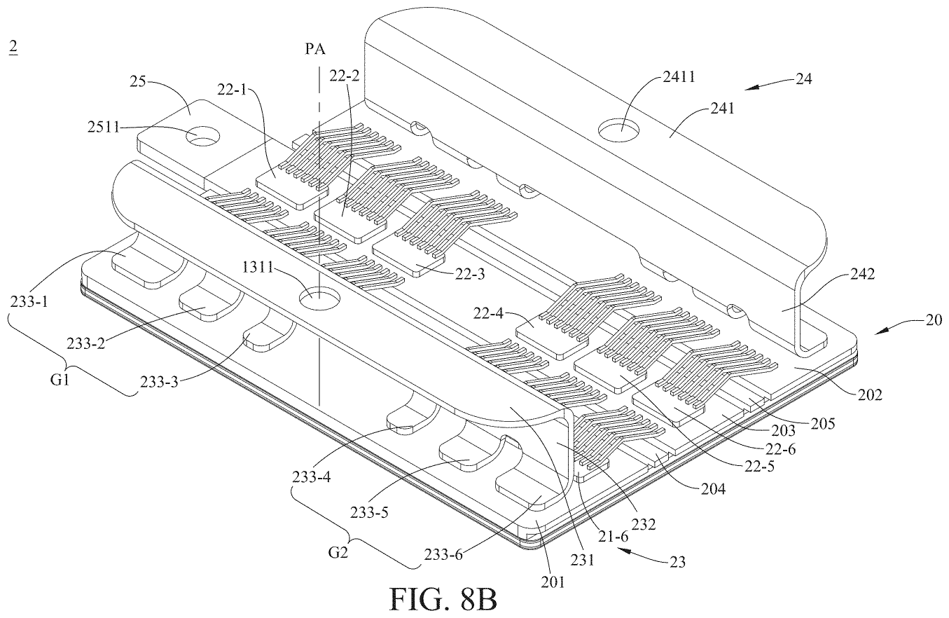

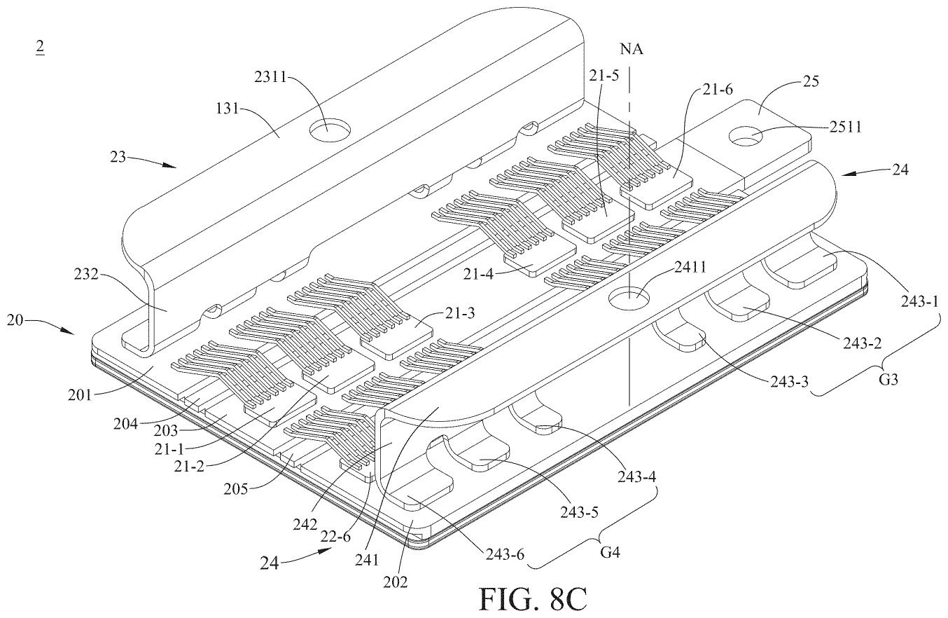

Please refer to FIG. 8A, FIG. 8B and FIG. 8C, which are structural diagrams of a high power module 2 in accordance with a second embodiment of the disclosure. As shown in FIG. 8A, the high power module 2 includes a substrate 20, six first power chips 21-1, 21-2, 21-3, 21-4, 21-5, 21-6, six second power chips 22-1, 22-2, 22-3, 22-4, 22-5, 22-6, a positive electrode plate 23, a negative electrode plate 24 and an output electrode plate 25.

The substrate 20 includes a first metal area 201, a second metal area 202, a third metal area 203, a fourth metal area 204, a fifth metal area 205, a first upper isolation area 206-1, a first lower isolation area 206-2, a second upper isolation area 207-1 and a second lower isolation area 207-2. The third metal area 203 is disposed between the first metal area 201 and the second metal area 202. The fourth metal area 204 is disposed between the first metal area 201 and the third metal area 203, and the fourth metal area 204 is connected to the gates of the first power chips 21-1, 21-2, 21-3, 21-4, 21-5, 21-6. The first upper isolation area 206-1 and the first lower isolation area 206-2 are disposed at the two sides of the fourth metal area 204 respectively in order to isolate the fourth metal area 204 from the first metal area 201 and the third metal area 203. The fifth metal area 205 is disposed between the second metal area 202 and the third metal area 203, and the fifth metal area 205 is connected to the gates of the second power chips 22-1, 22-2, 22-3, 22-4, 22-5, 22-6. The second upper isolation area 207-1 and the second lower isolation area 207-2 are disposed at the two sides of the fifth metal area 205 respectively in order to isolate the fifth metal area 205 from the third metal area 203 and the second metal area 202. Besides, the output electrode plate 25 is connected to one end of the third metal area 103 and has a screw hole 2511.

The fourth metal area 204 and the fifth metal area 205 are connected to an external gate driving circuit (not shown in the drawings). Alternatively, the gate driving circuit can be directly disposed on the first metal area 201, the second metal area 202, the third metal area 203, the fourth metal area 204 and the fifth metal area 205, which is similar to the structure shown in FIG. 2B.

As shown in FIG. 8B, the positive electrode 23 includes a positive terminal 231, a connection portion 232 and six positive pins 233-1, 233-2, 233-3, 233-4, 233-5, 233-6. The positive terminal 231 is connected to the positive pins 233-1, 233-2, 233-3, 233-4, 233-5, 233-6 via the connection portion 232, such that the positive electrode plate 23 can be C-shaped. The positive terminal 231 has a screw hole 2311. Likewise, the positive pins 233-1, 233-2, 233-3, 233-4, 233-5, 233-6 can be divided into two groups, the first group G1 (the positive pins 233-1, 233-2, 233-3) and the second group G2 (the positive pins 233-4, 233-5, 233-6). The first group G1 and the second group G2 are disposed at the two sides of the central axis PA of the positive electrode plate 23 respectively.

As shown in FIG. 8C, the negative electrode 24 includes a negative terminal 241, a connection portion 242 and six negative pins 243-1, 243-2, 243-3, 243-4, 243-5, 243-6. The negative terminal 241 is connected to the negative pins 243-1, 243-2, 243-3, 243-4, 243-5, 243-6 via the connection portion 242, such that the negative electrode plate 24 can be C-shaped. The negative terminal 241 has a screw hole 2411. Likewise, the negative pins 243-1, 243-2, 243-3, 243-4, 243-5, 243-6 can be divided into two groups, the third group G3 (the negative pins 243-1, 243-2, 243-3) and the fourth group G4 (the negative pins 243-4, 243-5, 243-6). The third group G3 and the fourth group G4 are disposed at the two sides of the central axis NA of the negative electrode plate 24 respectively.

The structures of the aforementioned elements of the high power module 2 are similar to those of the first embodiment, so will not be further described herein. The difference between this embodiment and the first embodiment is that the positive pins 233-1, 233-2, 233-3 have different widths and the positive pins 233-4, 233-5, 233-6 also have different widths. Similarly, the negative pins 243-1, 243-2, 243-3 have different widths and the negative pins 243-4, 243-5, 243-6 also have different widths.

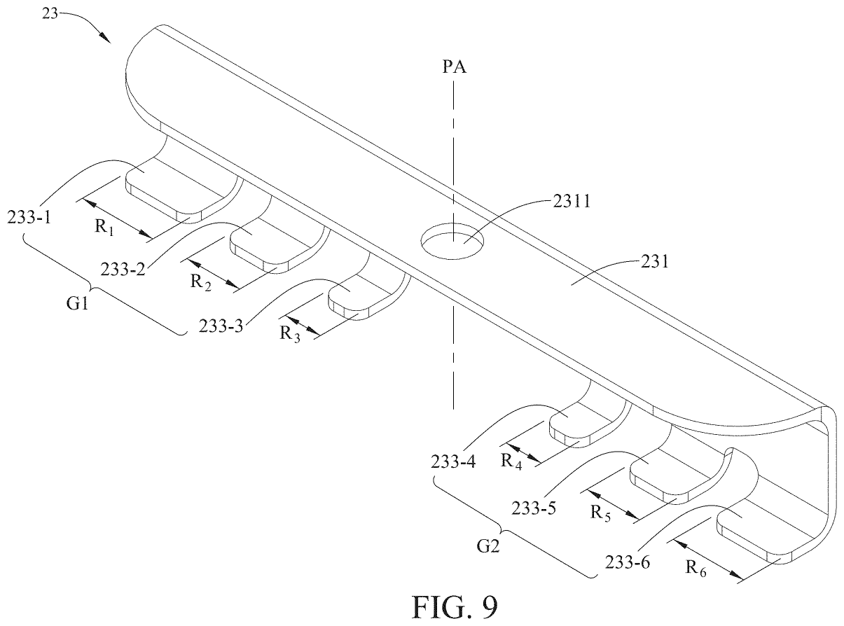

Please refer to FIG. 9, which is a stereogram view of a positive electrode plate 23 of the high power module 2 in accordance with the second embodiment of the disclosure. The widths of the positive pins 233-1, 233-2, 233-3, 233-4, 233-5, 233-6 are the channel widths of the current paths thereof. Therefore, in the embodiment, the widths of the positive pins 233-1, 233-2, 233-3, 233-4, 233-5, 233-6 are described as effective channel widths. As shown in FIG. 9A, the effective channel widths of the positive pins 233-1, 233-2, 233-3 of the first group G1 progressively increase in the direction away from the central axis PA of the positive electrode plate 23.

The effective channel widths of the positive pins 233-1, 233-2, 233-3 of the first group G1 can be adjusted by different ways. In the embodiment, the effective channel widths of the positive pins 233-1, 233-2, 233-3 of the first group G1 progressively increase based on an arithmetic sequence in the direction away from the central axis PA of the positive electrode plate 23 (i.e. the effective channel widths of the positive pins 233-1, 233-2, 233-3 progressively increase from the positive pin 233-3 to the positive pin 233-1), as shown in Equation (6) given below:

R₁(n₁−1)/(n₁+1),R₁n₁/(n₁+1),R₁ (6)

In Equation (6), the effective channel width R₃ of the positive pin 233-3 is R₁(n₁−1)/(n₁+1). The effective channel width R₂ of the positive pin 233-2 is R₁n₁/(n₁+1). The effective channel width of the positive pin 233-1 is R₁.

The common difference of the arithmetic sequence is the effective channel width R₁ of the positive pin 233-1, which is most away from the central axis PA of the positive electrode plate 23, divided by the total quantity (n₁+1) of the positive pins 233-1, 233-2, 233-3 of the first group G1 and the gate driving circuit (counted as one), as shown in Equation (7):

(1/n₁+1)*R₁ (7)

In Equation (7), n₁ stands for the quantity of the positive pins 233-1, 233-2, 233-3 of the first group G1. R₁ stands for the effective channel width of the positive pin 233-1 which is most away from the central axis PA of the positive electrode plate 23. In the embodiment, the effective channel width R₃ of the positive pin 233-3 is R₁/2. The effective channel width R₂ of the positive pin 233-2 is 3R₁/4. The effective channel width of the positive pin 233-1 is R₁.

In a similar way, the effective channel widths of the positive pins 233-4, 233-5, 233-6 of the second group G2 progressively increase in the direction away from the central axis PA of the positive electrode plate 23.

In the embodiment, the effective channel widths of the positive pins 233-4, 233-5, 233-6 of the second group G2 progressively increase based on an arithmetic sequence in the direction away from the central axis PA of the positive electrode plate 23 (i.e. the effective channel widths of the positive pins 233-4, 233-5, 233-6 progressively increase from the positive pin 233-4 to the positive pin 233-6), as shown in Equation (8) given below:

R₆(n₂−1)/(n₂+1),R₆n₂/(n₂+1),R₆ (8)

In Equation (8), the effective channel width R₄ of the positive pin 233-4 is R₆(n₂−1)/(n₂+1). The effective channel width R₅ of the positive pin 233-5 is R₆n₂/(n₂+1). The effective channel width of the positive pin 233-6 is R₆.

The common difference of the arithmetic sequence is the effective channel width R₆, of the positive pin 233-6 which is most away from the central axis PA of the positive electrode plate 23, divided by the total quantity (n₂+1) of the positive pins 233-4, 233-5, 233-6 of the second group G2 and the gate driving circuit, as shown in Equation (9):

(1/n₂+1)*R₆ (9)

In Equation (9), n₂ stands for the quantity of the positive pins 233-4, 233-5, 233-6 of the second group G2. R₆ stands for the effective channel width of the positive pin 233-6 which is most away from the central axis PA of the positive electrode plate 23. In the embodiment, the effective channel width R₄ of the positive pin 233-4 is R₆/2. The effective channel width R₅ of the positive pin 233-5 is 3R₆/4. The effective channel width of the positive pin 233-6 is R₆.

Alternatively, the effective channel widths of the positive pins 233-1, 233-2, 233-3, 233-4, 233-5, 233-6 can progressively increase based on other arithmetic sequences, which can also realize similar technical effect.

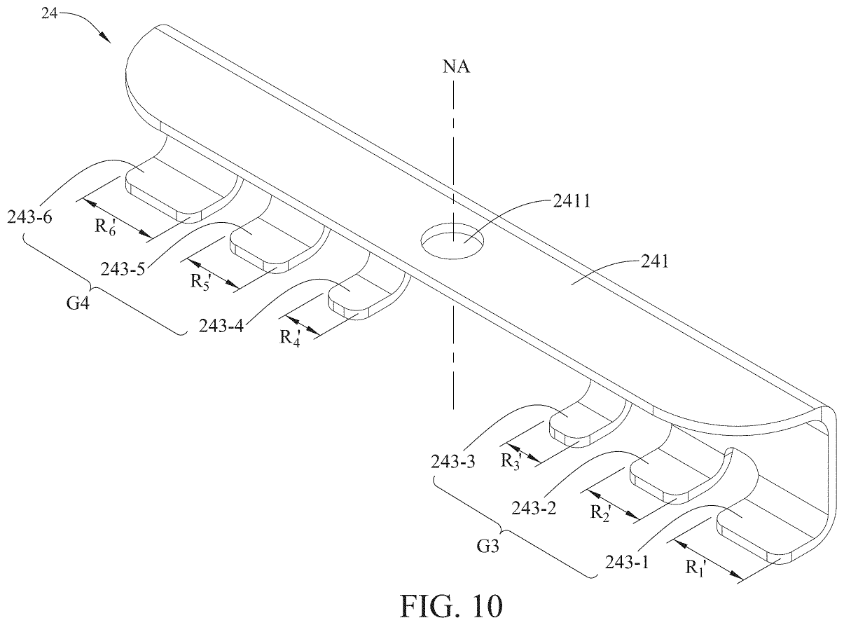

Please refer to FIG. 10, which is a stereogram view of a negative electrode plate 24 of the high power module 2 in accordance with the second embodiment of the disclosure. The difference between this embodiment and the first embodiment is that the negative pins 243-1, 243-2, 243-3 have different widths and the negative pins 243-4, 243-5, 243-6 also have different widths. As shown in FIG. 10, the effective channel widths of the negative pins 243-1, 243-2, 243-3 of the third group G3 progressively increase in the direction away from the central axis NA of the negative electrode plate 24.

The effective channel widths of the negative pins 243-1, 243-2, 243-3 of the third group G3 can be adjusted by different ways. In the embodiment, as shown in FIG. 10, the effective channel widths of the negative pins 243-1, 243-2, 243-3 of the third group G3 progressively increase based on an arithmetic sequence in the direction away from the central axis NA of the negative electrode plate 24 (i.e. the effective channel widths of the negative pins 243-1, 243-2, 243-3 progressively increase from the negative pin 243-3 to the negative pin 243-1, as shown in Equation (10) given below:

R₁′(n₃−1)/(n₃+1),R₁′n₃/(n₃+1),R₁′ (10)

The common difference of the arithmetic sequence is as shown in Equation (11):

(1/n₃+1)*R₁′ (11)

In Equation (11), n₃ stands for the quantity of the negative pins 243-1, 243-2, 243-3 of the third group G3. R₁′ stands for the effective channel width of the negative pin 243-1, which is most away from the central axis NA of the negative electrode plate 24. In the embodiment, the effective channel width R₃′ of the negative pin 243-3 is R₁′/2. The effective channel width R₂′ of the negative pin 243-2 is 3R₁′/4. The effective channel width of the negative pin 243-1 is R₁.

Likewise, the effective channel widths of the negative pins 243-4, 243-5, 243-6 of the fourth group G4 also progressively increase in the direction away from the central axis NA of the negative electrode plate 24.

In the embodiment, the effective channel widths of the negative pins 243-4, 243-5, 243-6 of the fourth group G4 progressively increase based on an arithmetic sequence in the direction away from the central axis NA of the negative electrode plate 24 (i.e. the effective channel widths of the negative pins 243-4, 243-5, 243-6 progressively increase from the negative pin 243-4 to the negative pin 243-6, as shown in Equation (12) given below:

R₆′(n₄−1)/(n₄+1),R₆′n₄/(n₄+1),R₆′ (12)

The common difference of the arithmetic sequence is as shown in Equation (13):

(1/n₄+1)*R₆′. (13)

In Equation (13), n₄ stands for the quantity of the negative pins 243-4, 243-5, 243-6 of the fourth group G4. R₆′ stands for the effective channel width of the negative pin 243-6, which is most away from the central axis NA of the negative electrode plate 24. In the embodiment, the effective channel width R₄′ of the negative pin 243-4 is R₆′/2. The effective channel width R₅′ of the negative pin 243-5 is 3R₆′/4. The effective channel width of the negative pin 243-6 is R₆′. The structure of the negative electrode plate 24 is analogous to that of the positive electrode plate 24, so will not be further described herein.

Alternatively, the effective channel widths of the negative pins 243-1, 243-2, 243-3, 243-4, 243-5, 243-6 can progressively increase based on other arithmetic sequences, which can also attain similar technical effect.

The distances between of the positive pins 233-1, 233-2, 233-3, 233-4, 233-5, 233-6 and the screw hole 2311 of the positive terminal 231 (the input point of current) are different to each other. Also, the distances between of the negative pins 243-1, 243-2, 243-3, 243-4, 243-5, 243-6 and the screw hole 2411 (the input point of current) of the negative terminal 241 are different to each other. For the reason, the high power module 2 may have non-uniform current density, which influences the performance of the high power module 2. However, the above special structure design of the embodiment can allow the positive pins 233-1, 233-2, 233-3, 233-4, 233-5, 233-6 and the negative pins 243-1, 243-2, 243-3, 243-4, 243-5, 243-6 have different effective channel widths in order to compensate for the above problem of non-uniform current density. Accordingly, the performance of the high power module 2 can be improved.

The embodiment just exemplifies the disclosure and is not intended to limit the scope of the disclosure. Any equivalent modification and variation according to the spirit of the disclosure is to be also included within the scope of the following claims and their equivalents.

It is worthy to point out that the stray inductance of currently available high power modules is very hard to be less than 10 nH (nano henry) because of the defective circuit design thereof. Thus, the currently available high power modules cannot be effectively applied to various vehicles or other relevant equipment. However, according to one embodiment of the disclosure, as shown in FIG. 8B and FIG. 8C, the positive electrode plate 23 and the negative electrode plate 24 of the high power module 2 are C-shaped. In addition, the direction of the opening of the positive electrode plate 23 is opposite to the direction of the opening of the negative electrode plate 24 (i.e. the positive electrode plate 23 and the negative electrode plate 24 are disposed back to back). Further, both of the positive electrode plate 23 and the negative electrode plate 24 can achieve back coupling or antiphase coupling. Accordingly, the stray inductance of the high power module 2 can be lowered.

Besides, according to one embodiment of the disclosure, as there is a distance between the positive electrode plate 23 and the negative electrode plate 24 of the high power module 2, the positive terminal 231 does not overlap the negative terminal 241 in the vertical direction (the normal vector of the substrate 20). In addition, both of the positive electrode plate 23 and the negative electrode plate 24 can achieve back coupling or antiphase coupling. Accordingly, the stray inductance of the high power module 2 can be further decreased.

Moreover, according to one embodiment of the disclosure, the high power module 2 have the widened positive terminal 231, negative terminal 241 and output terminal 251 because of the special structure design thereof, which can increase the sectional areas of these terminals. Hence, the stray inductance of the high power module 2 can be further reduced.

Furthermore, currently available high power modules are likely to suffer the problem of non-uniform current density due to the defective circuit design and structure design, which further deteriorates the performance thereof. However, according to one embodiment of the disclosure, as shown in FIG. 9, the positive electrode plate 23 includes six positive pins 233-1, 233-2, 233-3, 233-4, 233-5, 233-6 and the effective channel widths of the positive pins 233-1, 233-2, 233-3, 233-4, 233-5, 233-6 progressively increase based on an arithmetic sequence in the direction away from the central axis PA of the positive electrode plate 23, as shown in FIG. 10A-FIG. 10B. In addition, the negative pins 243-1, 243-2, 243-3, 243-4, 243-5, 243-6 also have the corresponding structures. Accordingly, the high power module 2 can attain uniform currently density.

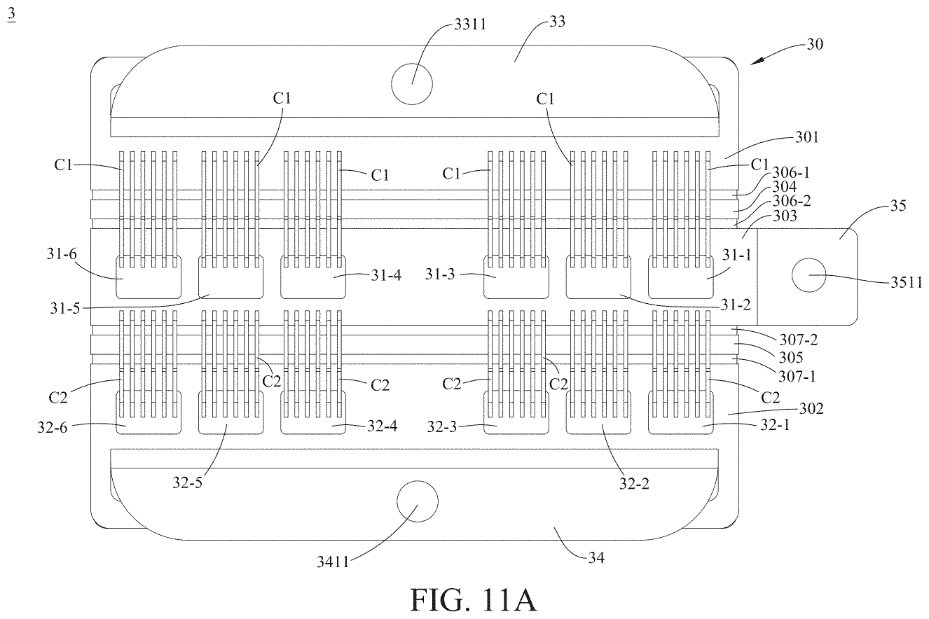

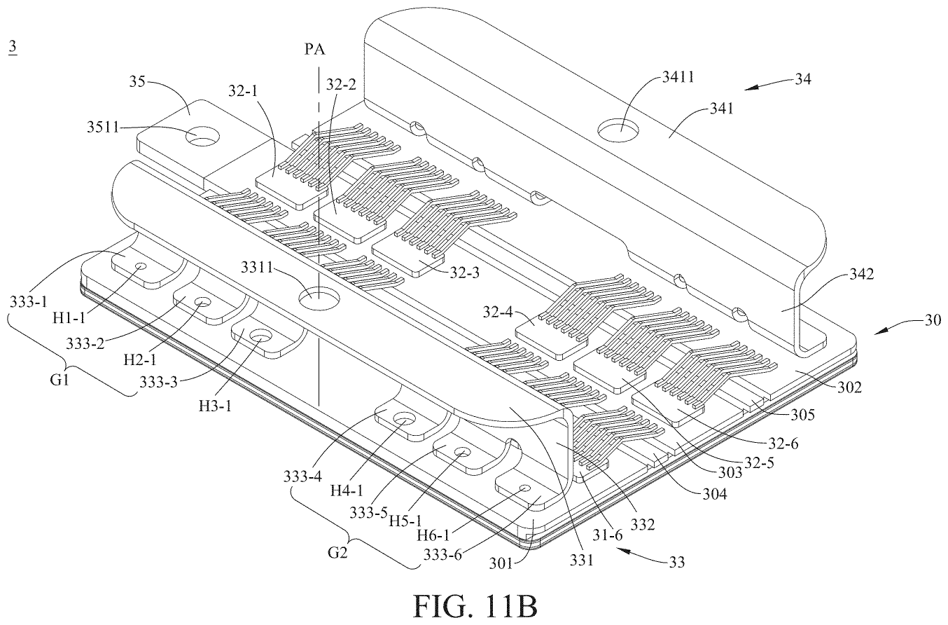

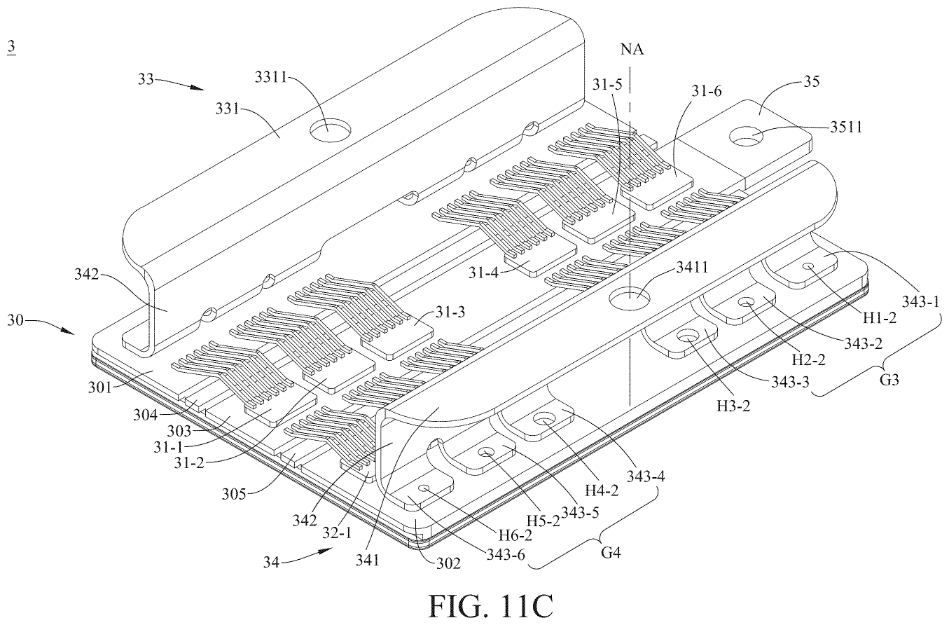

Please refer to FIG. 11A, FIG. 11B and FIG. 11C, which are structural diagrams of a high power module 3 in accordance with a third embodiment of the disclosure. As shown in FIG. 11A, the high power module 3 includes a substrate 30, six first power chips 31-1, 31-2, 31-3, 31-4, 31-5, 31-6, six second power chips 32-1, 32-2, 32-3, 32-4, 32-5, 32-6, a positive electrode plate 33, a negative electrode plate 34 and an output electrode plate 35.

The substrate 30 includes a first metal area 301, a second metal area 302, a third metal area 303, a fourth metal area 304, a fifth metal area 305, a first upper isolation area 306-1, a first lower isolation area 306-2, a second upper isolation area 307-1 and a second lower isolation area 307-2. The output electrode plate 35 has a screw hole 3511.

The fourth metal area 304 and the fifth metal area 305 are connected to an external gate driving circuit (not shown in the drawings). Alternatively, the gate driving circuit can be directly disposed on the first metal area 301, the second metal area 302, the third metal area 303, the fourth metal area 304 and the fifth metal area 305, which is similar to the structure shown in FIG. 2B.

As shown in FIG. 11B, the positive electrode plate 33 includes a positive terminal 331, a connection portion 332 and six positive pins 333-1, 333-2, 333-3, 333-4, 333-5, 333-6. The positive terminal 331 has a screw hole 3311. Likewise, the positive pins 333-1, 333-2, 333-3, 333-4, 333-5, 333-6 can be divided into two groups, the first group G1 (the positive pins 333-1. 333-2, 333-3) and the second group G2 (the positive pins 333-4, 333-5, 333-6).

As shown in FIG. 11C, the negative electrode plate 34 includes a negative terminal 341, a connection portion 342 and six negative pins 343-1, 343-2, 343-3, 343-4, 343-5, 343-6. The negative terminal 341 has a screw hole 3411. Similarly, the negative pins 343-1, 343-2, 343-3, 343-4, 343-5, 343-6 can be divided into two groups, the third group G3 (the negative pins 343-1. 343-2, 343-3) and the fourth group G4 (the negative pins 343-4, 343-5, 343-6).

The structures of the aforementioned elements of the high power module 3 are similar to those of the first embodiment, so will not be further described herein. The difference between this embodiment and the first embodiment is that the positive pins 333-1, 333-2, 333-3 have through holes H1-1, H2-1, H3-1 respectively and the positive pins 333-4, 333-5, 333-6 have through holes H4-1, H5-1, H6-1 respectively. In a similar way, the negative pins 343-1, 343-2, 343-3, 343-4, 343-5, 343-6 also have through holes H1-2, H2-2, H3-2, H4-2, H5-2, H6-2 respectively.

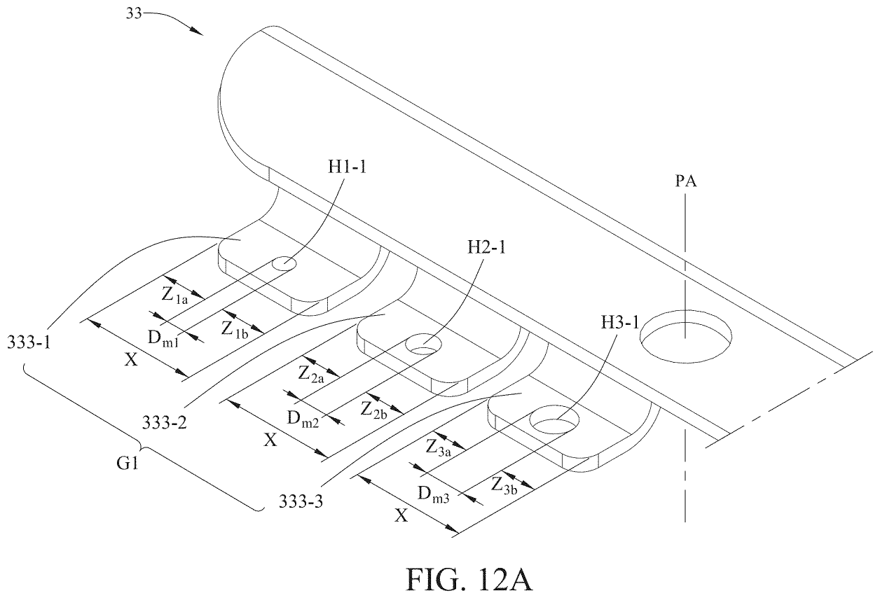

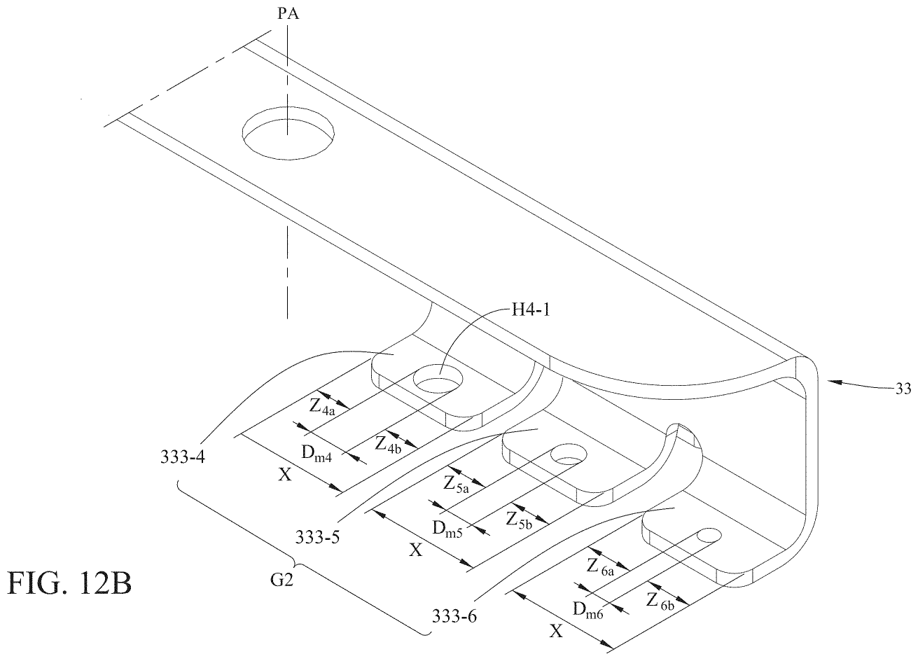

Please refer to FIG. 12A and FIG. 12B, which are local enlarged views of a positive electrode plate 33 of the high power module 3 in accordance with the third embodiment of the disclosure. The effective channel widths (the widths of the channel which the currents pass through) of the positive pins 333-1, 333-2, 333-3, 333-4, 333-5, 333-6 can be obtained by deducting the diameters of the through holes H1-1, H2-1, H3-1, H4-1, H5-1, H6-1 from the widths of the corresponding positive pins 333-1, 333-2, 333-3, 333-4, 333-5, 333-6 respectively. As shown in FIG. 12A, the areas of the through holes H1-1, H2-1, H3-1 of the positive pins 333-1, 333-2, 333-3 of the first group G1 gradually decrease in the direction away from the central axis PA of the positive electrode plate 33. Therefore, the effective channel widths of the positive pins 333-1, 333-2, 333-3 of the first group G1 progressively increase in the direction away from the central axis PA of the positive electrode plate 33.

The effective channel widths of the positive pins 333-1, 333-2, 333-3 of the first group G1 can be adjusted by different ways. In the embodiment, the positive pins 333-1, 333-2, 333-3 have the same width, but the sizes/areas of the through holes H1-1, H2-1, H3-1 in descending order is H3-1>H2-1>H1-1. Therefore, the effective channel width of the positive pin 333-1 is calculated by deducting the diameter Dₘ₁ of the through hole H1-1 from the width X of the positive pin 333-1, as shown in Equation (14) given below:

X-Dₘ₁=Z₁ (14)

In Equation (14), X stands for the width of the positive pin 333-1 (since the positive pins 333-1, 333-2, 333-3, 333-4, 333-5, 333-6 have the same width, all of which are marked as X). Dₘ₁ stands for the diameter of the through hole H1-1. Z₁ stands for the effective channel width of the positive pin 333-1 (Z₁=Z₁ₐ+Z_{1b}).

The effective channel width Z₂ of the positive pin 333-2 is calculated by deducting the diameter Dₘ₂ of the through hole H2-1 from the width X of the positive pin 333-2, as shown in Equation (15) given below:

X−Dₘ₂=Z₂ (15)

In Equation (15), X stands for the width of the positive pin 333-2. Dₘ₂ stands for the diameter of the through hole H2-1. Z₂ stands for the effective channel width of the positive pin 333-2 (Z₂=Z₂ₐ+Z_{2b}).

The effective channel width Z₃ of the positive pin 333-3 is calculated by deducting the diameter Dₘ₃ of the through hole H3-1 from the width X of the positive pin 333-3, as shown in Equation (16) given below:

X-Dₘ₃=Z₃ (16)

In Equation (16), X stands for the width of the positive pin 333-3. Dₘ₃ stands for the diameter of the through hole H3-1. Z₃ stands for the effective channel width of the positive pin 333-3 (Z₃=Z₃ₐ+Z_{3b}).

The effective channel widths of the positive pins 333-1, 333-2, 333-3 of the first group G1 can be adjusted by different ways. In the embodiment, the effective channel widths of the positive pins 333-1, 333-2, 333-3 are the widths of the positive pins 333-1, 333-2, 333-3 minus the diameters of the corresponding through holes H1-1, H2-1, H3-1 respectively. Thus, the effective channel widths of the positive pins 333-1, 333-2, 333-3 progressively increase based on an arithmetic sequence in the direction away from the central axis PA of the positive electrode plate 33 (i.e. the effective channel widths of the positive pins 333-1, 333-2, 333-3 progressively increase from the positive pin 333-3 to the positive pin 333-1), as shown in Equation (17) given below:

Z₁(n₁−1)/(m+1),Z₁n₁/(m+1),Z₁ (17)

In Equation (17), the effective channel width of the positive pin 333-3 is Z₁(n₁−1)/(n₁+1). The effective channel width of the positive pin 333-2 is Z₁n₁/(n₁+1). The effective channel width of the positive pin 333-1 is Z₁.

The common difference of the arithmetic sequence is the effective channel width Z₁ of the positive pin 333-1, which is most away from the central axis PA of the positive electrode plate 33, divided by the total quantity (n₁+1) of the positive pins 333-1. 333-2. 333-3 of the first group G1 and the gate driving circuit (counted as one), as shown in Equation (18) given below:

(1/n₁+1)*Z₁ (18)

In Equation (18), n₁ stands for the quantity of the positive pins 333-1, 333-2, 333-3 of the first group G1. Z₁ stands for the effective channel width of the positive pin 333-1 which is most away from the central axis PA of the positive electrode plate 33. As described above, the effective channel width Z₁ is calculated by deducting the diameter of the corresponding through hole H1-1 from the width of the positive pin 333-1. In the embodiment, the effective channel width Z₃ of the positive pin 333-3 is Z₁/2. The effective channel width Z₂ of the positive pin 333-2 is 3Z₁/4. The effective channel width of the positive pin 333-1 is Z₁.

As shown in FIG. 12B, the areas of the through holes H4-1, H5-1, H6-1 of the positive pins 333-4, 333-5, 333-6 of the second group G2 gradually decrease in the direction away from the central axis PA of the positive electrode plate 33. Therefore, the effective channel widths Z₄, Z₅, Z₆ of the positive pins 333-4, 333-5, 333-6 of the second group G2 progressively increase in the direction away from the central axis PA of the positive electrode plate 33.

The effective channel widths Z₄, Z₅, Z₆ of the positive pins 333-4, 333-5, 333-6 of the second group G2 can be adjusted by different ways. In the embodiment, the positive pins 333-4, 333-5, 333-6 have the same width, but the sizes of the through holes H4-1, H5-1, H6-1 in descending order is H4-1>H5-1>H6-1. Therefore, the effective channel width of the positive pin 333-4 is calculated by deducting the diameter Dₘ₄ of the through hole H4-1 from the width X of the positive pin 333-4, as shown in Equation (19) given below:

X−Dₘ₄=Z₄ (19)

In Equation (19), X stands for the width of the positive pin 333-4. Dₘ₄ stands for the diameter of the through hole H4-1. Z₄ stands for the effective channel width of the positive pin 333-4 (Z₄=Z₄ₐ+Z_{4b}).

The effective channel width Z₅ of the positive pin 333-5 is calculated by deducting the diameter Dₘ₅ of the through hole H5-1 from the width X of the positive pin 333-5, as shown in Equation (20) given below:

X-Dₘ₅=Z₅ (20)

In Equation (20), X stands for the width of the positive pin 333-5. Dₘ₅ stands for the diameter of the through hole H5-1. Z₅ stands for the effective channel width of the positive pin 333-5 (Z₅=Z₅ₐ+Z_{5b}).

The effective channel width Z₆ of the positive pin 333-6 is calculated by deducting the diameter Dₘ₆ of the through hole H6-1 from the width X of the positive pin 333-6, as shown in Equation (21) given below:

X-Dₘ₆=Z₆ (21)

In Equation (21), X stands for the width of the positive pin 333-6. Dₘ₆ stands for the diameter of the through hole H6-1. Z₆ stands for the effective channel width of the positive pin 333-6 (Z₆=Z₆ₐ+Z_{6b}).

The effective channel widths Z₄, Z₅, Z₆ of the positive pins 333-4, 333-5, 333-6 of the second group G2 can be adjusted by different ways. In the embodiment, the effective channel widths of the positive pins 333-4, 333-5, 333-6 are the widths X of the positive pins 333-4, 333-5, 333-6 minus the diameters Dₘ₄, Dₘ₅, Dₘ₆ of the corresponding through holes H4-1, H5-1, H6-1 respectively. Thus, the effective channel widths Z₄, Z₅, Z₆ of the positive pins 333-4, 333-5, 333-6 progressively increase based on an arithmetic sequence in the direction away from the central axis PA of the positive electrode plate 33 (i.e. the effective channel widths of the positive pins 333-4, 333-5, 333-6 progressively increase from the positive pin 333-4 to the positive pin 333-6), as shown in Equation (22) given below:

Z₆(n₂−1)/(n₂+1),Z₆n₂/(n₂+1),Z₆ (22)

In Equation (23), the effective channel width of the positive pin 333-4 is Z₆(n₂−1)/(n₂+1). The effective channel width of the positive pin 333-5 is Z₆n₂/(n₂+1). The effective channel width of the positive pin 333-6 is Z₆.

The common difference of the arithmetic sequence is the effective channel width Z₆ of the positive pin 333-6, which is most away from the central axis PA of the positive electrode plate 33, divided by the total quantity (n₂+1) of the positive pins 333-4. 333-5. 333-6 of the second group G2 and the gate driving circuit, as shown in Equation (23) given below:

(1/n₂+1)*Z₆ (23)

In Equation (23), n₂ stands for the quantity of the positive pins 333-4, 333-5, 333-6 of the second group G2. Z₆ stands for the effective channel width of the positive pin 333-6 which is most away from the central axis PA of the positive electrode plate 33. As described above, the effective channel width Z₆ is calculated by deducting the diameter of the corresponding through hole H6-1 from the width of the positive pin 333-6. In the embodiment, the effective channel width Z₄ of the positive pin 333-4 is Z₆/2. The effective channel width Z₅ of the positive pin 333-5 is 3Z₆/4. The effective channel width of the positive pin 333-6 is Z₆.

The structure of the negative electrode plate 34 is identical to that of the positive electrode plate 33, so will not be further described herein. In the embodiment, the effective channel width Z₃′ of the negative pin 343-3 is Z₁′/2. The effective channel width Z₂′ of the negative pin 343-2 is 3Z₁′/4. The effective channel width of the negative pin 343-1 is Z₁′. The effective channel width Z₆′ of the negative pin 343-4 is Z₆′/2. The effective channel width Z₅′ of the negative pin 343-5 is 3Z₆′/4. The effective channel width of the negative pin 343-6 is Z₆′.

The distances between the positive pins 333-1, 333-2, 333-3, 333-4, 333-5, 333-6 and the screw hole 3311 of the positive terminal 331 (the input point of current) are different to each other. Also, the distances between the negative pins 343-1, 343-2, 343-3, 343-4, 343-5, 343-6 and the screw hole 3411 (the input point of current) of the negative terminal 341 are different to each other. For the reason, the high power module 3 may have non-uniform current density, which influences the performance of the high power module 3. However, the above special structure design of the embodiment allows the positive pins 333-1, 333-2, 333-3, 333-4, 333-5, 333-6 and the negative pins 343-1, 343-2, 343-3, 343-4, 343-5, 343-6 to have different effective channel widths in order to compensate for the above problem of non-uniform current density.

Accordingly, the performance of the high power module 3 can be further enhanced. As shown in FIG. 11B and FIG. 12A˜FIG. 12B, the positive electrode plate 33 and the negative electrode plate 34 of the high power module 3 are C-shaped. Besides, the direction of the opening of the positive electrode plate 33 is contrary to the direction of the opening of the negative electrode plate 34 (i.e. the positive electrode plate 33 and the negative electrode plate 34 are disposed back to back). Moreover, both of the positive electrode plate 33 and the negative electrode plate 34 can attain back coupling or antiphase coupling. Accordingly, the stray inductance of the high power module 3 can be diminished.

The embodiment just exemplifies the disclosure and is not intended to limit the scope of the disclosure. Any equivalent modification and variation according to the spirit of the disclosure is to be also included within the scope of the following claims and their equivalents.

To sum up, according to one embodiment of the disclosure, the stray inductances of the positive terminal (P terminal/DC+) and the negative terminal (N terminal/DC−) can be less than 10 nH (nano henry) and the current density thereof can be less than 20A/mm² (when the high power module operates at the power below 10 kw). The other embodiments of the disclose can also realize similar technical effect. The positive electrode plate and the negative electrode plate of each high power module are C-shaped. In addition, the direction of the opening of the positive electrode plate is opposite to the direction of the opening of the negative electrode plate (i.e. the positive electrode plate and the negative electrode plate are disposed back to back). Further, both of the positive electrode plate and the negative electrode plate can achieve back coupling or antiphase coupling. Accordingly, the stray inductance of the high power module can be lowered, so can be comprehensively applied to various vehicles and other relevant equipment, such as electric vehicles, motorcycles, buses, trucks, charging stations, etc.

Besides, according to one embodiment of the disclosure, as there is a distance between the positive electrode plate and the negative electrode plate of the high power module, the positive terminal does not overlap the negative terminal in the vertical direction (the normal vector of the substrate). In addition, both of the positive electrode plate and the negative electrode plate can achieve back coupling or antiphase coupling. Accordingly, the stray inductance of the high power module can be further decreased.

Moreover, according to one embodiment of the disclosure, the high power module have the widened positive terminal, negative terminal and output terminal because of the special structure design thereof, which can increase the sectional areas of these terminals. For the reason, the stray inductance of the high power module can be further decreased.

In one embodiment of the disclosure, the positive electrode plate of the high power module includes several positive pins and the effective channel widths of the positive pins progressively increase based on an arithmetic sequence in the direction away from the central axis of the positive electrode plate. In one embodiment, the negative pins also have the corresponding structures. In one embodiment, the effective channel widths of the positive pins are adjusted by changing the sizes of several holes thereon. Accordingly, the high power module can achieve uniform currently density.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A high power module, comprising:
a substrate, comprising a first metal area, a second metal area, and a third metal area disposed between the first metal area and the second metal area;
a plurality of first power chips, disposed on the third metal area and connected to the first metal area via a plurality of first connection elements;
a plurality of second power chips, disposed on the second metal area and connected to the third metal area via a plurality of second connection elements;
a positive electrode plate, being C-shaped and connected to the first metal area;
a negative electrode plate, being C-shaped and connected to the second metal area, and a direction of an opening of the negative electrode plate is contrary to a direction of an opening of the positive electrode plate; and
an output electrode plate, connected to one end of the third metal area.

2. The high power module of claim 1, further comprising a fourth metal area and a fifth metal area, wherein the fourth metal area is disposed between the first metal area and the third metal area and connected to gates of the first power chips; the fifth metal area disposed between the second metal area and the third metal area and connected to gates of the second power chips; the fourth metal area and the fifth metal area are connected to an external gate driving circuit.

3. The high power module of claim 1, further comprising a gate driving circuit, a fourth metal area and a fifth metal area, wherein the fourth metal area is disposed between the first metal area and the third metal area, and connected to gates of the first power chips; the fifth metal area is disposed between the second metal area and the third metal area, and connected to gates of the second power chips; the gate driving circuit is disposed on the first metal area, the second metal area, the third metal area, the fourth metal area and the fifth metal area, and connected to the fourth metal area and the fifth metal area.

4. The high power module of claim 3, wherein the first metal area comprises a first slot;
the second metal area comprises a second slot; the third metal comprises a third slot;
the fourth metal area comprises a fourth slot; the fifth metal area comprises a fifth slot;
the gate driving circuit is disposed in a space formed by the first slot, the second slot, the third slot, the fourth slot and the fifth slot.

5. The high power module of claim 1, wherein the substrate comprises a slot and a gate driving circuit is disposed in the slot, whereby the gate driving circuit is wrapped by the substrate, the first metal area, the second metal area and the third metal area.

6. The high power module of claim 1, wherein the first power chips are arranged in a straight line to form an array and connected in parallel, and the second power chips are arranged in a straight line to form another array and connected in parallel.

7. The high power module of claim 1, wherein the first power chips are symmetrical to the second power chips and the positive electrode plate is symmetrical to the negative electrode plate.

8. The high power module of claim 1, wherein the output electrode plate is a flat plate, parallel to the third metal area, and the output electrode plate and the third metal area are located on the same plane.

9. The high power module of claim 1, wherein a width of the output electrode plate is greater than a width of one the first power chips and less than a total width of two of the first power chips.

10. The high power module of claim 1, wherein the positive electrode plate is parallel to the negative electrode plate and there is a distance between the positive electrode plate and the negative electrode plate.

11. The high power module of claim 1, wherein a width of the positive electrode plate is greater than a sum of a total width of the first power chips, a width of a central recess of the positive electrode plate and a total of intervals between the first power chips, and less than a width of the first metal area.

12. The high power module of claim 1, wherein the positive electrode plate comprises a positive terminal, a connection portion and a plurality of positive pins; a width of one connection end, the positive terminal connecting to the connection portion, is equal to a width of the positive electrode plate; a width of the other end of the positive terminal is less than the width of the positive terminal, and the width of the other end of the positive terminal is greater than or equal to a value of the width of the positive terminal subtracted by a total width of two of the first power chips.

13. The high power module of claim 1, wherein the positive electrode comprises a positive terminal, a connection portion and a plurality of positive pins; the positive pins are corresponding to the first power chips in position and the positive terminal is connected to the positive pins via the connection portion, whereby the positive electrode plate is C-shaped, and the positive terminal and the positive pins are located on two different planes parallel to each other.

14. The high power module of claim 13, wherein a width of the positive pin is greater than or equal to a width of the first power chip, and the width of the positive pin is less than a sum of the width of each of the first power chip and an interval between two of the first power chips adjacent to each other.

15. The high power module of claim 13, wherein the positive pins are divided into a first group and a second group; the first group and the second group are disposed at two sides of a central axis of the positive electrode plate respectively, and effective channel widths of the positive pins of the first group and effective channel widths of the positive pins of the second group progressively increase in a direction away from the central axis of the positive electrode plate.

16. The high power module of claim 13, wherein the positive pins are divided into a first group and a second group; the first group and the second group are disposed at two sides of a central axis of the positive electrode plate respectively, and effective channel widths of the positive pins of the first group and effective channel widths of the positive pins of the second group progressively increase based on an arithmetic sequence in a direction away from the central axis of the positive electrode plate.

17. The high power module of claim 16, wherein a common difference of the arithmetic sequence is the effective channel width of the positive pin which is most away from the central axis of the positive electrode plate, divided by a total quantity of the positive pins of the first group and a gate driving circuit or a total quantity of the positive pins of the second group and the gate driving circuit.

18. The high power module of claim 13, wherein the positive pins are divided into a first group and a second group; the first group and the second group are disposed at two sides of a central axis of the positive electrode plate respectively, and each of the positive pins has a through hole, and areas of the through holes of the positive pins of the first group and areas of the through holes of the positive pins of the second group progressively decrease in a direction away from the central axis of the positive electrode plate.

19. The high power module of claim 18, wherein effective channel widths of the positive pins are widths of the positive pins of the first group and widths of the positive pins of the second group minus diameters of the corresponding through holes respectively, and the effective channel widths of the positive pins progressively increase based on an arithmetic sequence in a direction away from the central axis of the positive electrode plate.

20. The high power module of claim 19, wherein a common difference of the arithmetic sequence is the effective channel width of the positive pin which is most away from the central axis of the positive electrode plate, divided by a total quantity of the positive pins of the first group and a gate driving circuit or a total quantity of the positive pins of the second group and the gate driving circuit.

21. The high power module of claim 1, wherein a width of the negative electrode plate is greater than a sum of a total width of the second power chips, a width of a central recess of the negative electrode plate and a total of intervals between the second power chips, and less than a width of the second metal area.

22. The high power module of claim 1, wherein the negative electrode plate comprises a negative terminal, a connection portion and a plurality of negative pins; a width of one connection end, the negative terminal connecting to the connection portion, is equal to a width of the negative electrode plate; a width of the other end of the negative terminal is less than the width of the negative terminal, and the width of the other end of the negative terminal is greater than or equal to a value of the width of the negative terminal subtracted by a total width of two of the second power chips.

23. The high power module of claim 1, wherein the negative electrode comprises a negative terminal, a connection portion and a plurality of negative pins; the negative pins are corresponding to the second power chips in position and the negative terminal is connected to the negative pins via the connection portion, whereby the negative electrode plate is C-shaped, and the negative terminal and the negative pins are located on two different planes parallel to each other.

24. The high power module of claim 23, wherein a width of the negative pin is greater than or equal to a width of the second power chip, and the width of the negative pin is less than a sum of the width of each of the second power chip and an interval between two of the second power chips adjacent to each other.

25. The high power module of claim 23, wherein the negative pins are divided into a third group and a fourth group; the third group and the fourth group are disposed at two sides of a central axis of the negative electrode plate respectively, and effective channel widths of the negative pins of the third group and effective channel widths of the negative pins of the fourth group progressively increase in a direction away from the central axis of the negative electrode plate.

26. The high power module of claim 23, wherein the negative pins are divided into a third group and a fourth group; the third group and the fourth group are disposed at two sides of a central axis of the negative electrode plate respectively, and effective channel widths of the negative pins of the third group and effective channel widths of the negative pins of the fourth group progressively increase based on an arithmetic sequence in a direction away from the central axis of the negative electrode plate.

27. The high power module of claim 26, wherein a common difference of the arithmetic sequence is the effective channel width of the negative pin which is most away from the central axis of the negative electrode plate, divided by a total quantity of the negative pins of the third group and a gate driving circuit or a total quantity of the negative pins of the fourth group and the gate driving circuit.

28. The high power module of claim 23, wherein the negative pins are divided into a third group and a fourth group; the third group and the fourth group are disposed at two sides of a central axis of the negative electrode plate respectively, and each of the negative pins has a through hole, and areas of the through holes of the negative pins of the third group and areas of the through holes of the negative pins of the fourth group progressively decrease in a direction away from the central axis of the negative electrode plate.

29. The high power module of claim 28, wherein effective channel widths of the negative pins are widths of the negative pins of the third group and widths of the negative pins of the fourth group minus diameters of the corresponding through holes respectively, and the effective channel widths of the negative pins progressively increase based on an arithmetic sequence in a direction away from the central axis of the negative electrode plate.

30. The high power module of claim 29, wherein a common difference of the arithmetic sequence is the effective channel width of the negative pin which is most away from the central axis of the negative electrode plate, divided by a total quantity of the negative pins of the third group and a gate driving circuit or a total quantity of the negative pins of the fourth group and the gate driving circuit.
